(19) United States
(12) Patent Application Publication
(10) Pub. No.: US 2025/0266074 A1
(43) Pub. Date: Aug. 21, 2025

(54) MEMORY DEVICE AND REFRESH METHOD THEREOF

(71) Applicant: Samsung Electronics Co., Ltd., Suwon-si (KR)

(72) Inventors: Jung Min You, Suwon-si (KR); YEONGGEOL SONG, Suwon-si (KR); DAEHYUN KIM, Suwon-si (KR); KYOMIN SOHN, Suwon-si (KR); KIJUN LEE, Suwon-si (KR); MYUNGKYU LEE, Suwon-si (KR); SUNGHYE CHO, Suwon-si (KR)

(21) Appl. No.: 18/894,183

(22) Filed: Sep. 24, 2024

(30) Foreign Application Priority Data
Feb. 19, 2024 (KR) 10-2024-0023544

(51) Int. Cl. G11C 11/406; G11C 29/18; H03K 19/20

(52) U.S. Cl. CPC G11C 11/406; G11C 29/18; H03K 19/20

(57) ABSTRACT

A memory device may include a refresh controller configured to generate a first control signal and a second control signal based on an activate command and a row address that corresponds to the activate command, an aggressor row determiner configured to determine the row address as an aggressor row address based on the first control signal, and a victim row determiner configured to determine a victim row address based on the aggressor row address, and determine whether to output the victim row address as a refresh address based on the second control signal. The memory device may be configured to perform a refresh on a row corresponding to the refresh address.

### CROSS-REFERENCE TO RELATED APPLICATION(S)

This application claims priority to and the benefit of Korean Patent Application No. 10-2024-0023544 filed in the Korean Intellectual Property Office on Feb. 19, 2024, the disclosure of which is incorporated herein by reference in its entirety.

### BACKGROUND OF THE INVENTION

### (a) Field of the Invention

The present invention relates to a memory device and a refreshing method.

### (b) Description of the Related Art

A volatile memory device such as a dynamic random-access memory (DRAM) may store data by storing charges to a capacitor of a memory cell, and may read data by determining the charges stored in the capacitor. The charges stored in the capacitor leak over time so the memory device may periodically perform a refresh operation.

A memory controller may randomly access the address of the memory device, and may frequently access specific addresses. As the density of memory cells in memory device increases, the charge of memory cells in adjacent rows may be affected by the voltage distribution in a certain row. In particular, when a certain row is intensively accessed as an attack, due to a voltage of an active state of a row, data stored in memory cells of another row adjacent to the row may be changed. This phenomenon is called a row hammer. Therefore, it is useful to efficiently improve a refresh operation of the memory device.

### SUMMARY

The present disclosure attempts to provide a memory device and a refresh method for processing aggressions.

An embodiment of the present disclosure, a memory device may include a refresh controller configured to generate a first control signal and a second control signal based on an activate command and a row address that corresponds to the activate command; an aggressor row determiner configured to determine the row address as an aggressor row address based on the first control signal; and a victim row determiner configured to determine a victim row address based on the aggressor row address, and determine whether to output the victim row address as a refresh address based on the second control signal. The memory device is configured to perform a refresh on a row corresponding to the refresh address.

An embodiment of the present disclosure, a memory device may include a memory cell array including a plurality of memory cells; and a refresh control circuit configured to determine an aggressor row address based on an active signal and a row address that corresponds to the active signal, determine a victim row address based on the aggressor row address, and determine a difference between a row corresponding to the aggressor row address and a row corresponding to a previous aggressor row address. When an absolute value of the difference is a reference value, the memory device is configured such that the refresh control circuit skips a refresh on the row corresponding to the victim row address that is previously refreshed or refreshes on another row.

An embodiment of the present disclosure, a refresh method of a memory device may include receiving an active signal and a row address that corresponds to the active signal; determining a first aggressor row based on the active signal and the row address; determining whether a first victim row adjacent to the first aggressor row repeats a previously refreshed row; determining a second aggressor row that is different from the first aggressor row when the first victim row repeats the same, and determining a second victim row adjacent to the second aggressor row to be refreshed; and determining the first victim row to be refreshed when the first victim row does not repeat the same.

### BRIEF DESCRIPTION OF THE DRAWINGS

FIG. 1 shows a block diagram of a memory system according to an embodiment.

FIG. 2 shows a block diagram of a memory device according to an embodiment.

FIG. 3 shows a block diagram of a refresh control circuit according to an embodiment.

FIG. 4 shows a block diagram of an aggressor row determiner according to an embodiment.

FIG. 5 shows a block diagram of a linear feedback shift register according to an embodiment.

FIG. 6 shows a block diagram of a victim row determiner according to an embodiment.

FIG. 7 shows a timing diagram illustrating a refresh operation of a memory device according to an embodiment.

FIG. 8 and FIG. 9 show a portion of a memory cell array of a memory device.

FIG. 10 shows a block diagram of a refresh control circuit according to an embodiment.

FIG. 11 shows a block diagram of an aggressor row determiner according to an embodiment.

FIG. 12 shows a block diagram of a victim row determiner according to an embodiment.

FIG. 13 shows a timing diagram illustrating a refresh operation of a memory device according to an embodiment.

FIG. 14 shows a flowchart of a refresh method according to an embodiment.

FIG. 15 shows a block diagram of a computing system according to an embodiment.

FIG. 16 shows a memory module according to an embodiment.

FIG. 17 shows a semiconductor package according to an embodiment.

### DETAILED DESCRIPTION OF THE EMBODIMENTS

In the following detailed description, only certain embodiments of the present invention have been shown and described, simply by way of illustration. As those skilled in the art would realize, the described embodiments may be modified in various different ways, all without departing from the spirit or scope of the present invention.

Accordingly, the drawings and description are to be regarded as illustrative in nature and not restrictive, and like reference numerals designate like elements throughout the specification. The sequence of operations or steps is not limited to the order presented in the claims or figures unless specifically indicated otherwise. The order of operations or steps may be changed, several operations or steps may be merged, a certain operation or step may be divided, and a specific operation or step may not be performed.

As used herein, the singular forms “a” and “an” are intended to include the plural forms as well, unless the context clearly indicates otherwise. Although the terms first, second, and the like may be used herein to describe various elements, components, steps and/or operations. These terms are only used to distinguish one element, component, step or operation from another element, component, step, or operation.

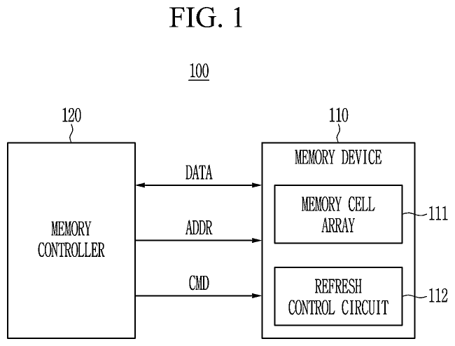

FIG. 1 shows a block diagram of a memory system according to an embodiment.

Referring to FIG. 1, a memory system 100 according to an embodiment may include a memory device 110 and a memory controller 120. In some embodiments, the memory device 110 and the memory controller 120 may be connected through a memory interface and may transmit and receive signals through the memory interface.

The memory device 110 may include a memory cell array 111 and a refresh control circuit 112. The memory cell array 111 may include a plurality of memory cells defined by a plurality of rows and a plurality of columns. In the present disclosure, the rows may be defined by word lines, and the columns may be defined by bit lines. The refresh control circuit 112 may detect an aggressor row (or an attack row) from among the plurality of rows, may determine a row address (a victim row address hereinafter) of a victim row to be refreshed based on a row address (an aggression row address hereinafter) of an aggressor row, and may output the victim row address. In some embodiments, the aggressor row may be a row hammer aggressor row, and the victim row may be a row that is a target of a row hammer care. In some embodiments, the refresh control circuit 112 may select the aggressor row address, and may output a refresh address based on the victim row addresses at a refresh time.

The refresh control circuit 112 may determine a refresh address so that the victim row address may not be repeatedly refreshed. For example, the refresh control circuit 112 may determine the aggressor row address, and may determine a difference or a difference value between the currently determined aggressor row address and the previous aggressor row address. Herein, the difference between two row addresses may mean a difference between two rows corresponding to the two row addresses. The difference between two rows may indicate how far a first row of the two rows is spaced from a second row of the two rows. For example, the difference has a positive value if the first row is disposed above the second row by the positive value of the number of rows, and the difference has a negative value if the first row is disposed below the second row by the negative value of the number of rows. For example, when the difference value between the first and second rows is ±2, a third row is disposed between the first and second rows. The refresh control circuit 112 may replace the victim row address with another row address based on the difference between the aggressor row addresses (i.e., the currently determined aggressor row address and the previous aggressor row address), or may skip the refresh of the row corresponding to the victim row address. Herein, replacing the victim row address with another row address may mean replacing a row corresponding to the victim row address with a row corresponding to another row address to be refreshed. For example, the refresh control circuit 112 may replace memory cells connected to a row (e.g., a victim row) corresponding to the victim row address with memory cells connected to a row corresponding to another row address, or may skip the refresh of memory cells connected to the row corresponding to the victim row address. Hence, the memory device 110 may increase defense performance and may reduce power consumption.

The memory controller 120 may provide a signal to the memory device 110 to control a memory operation of the memory device 110. The signal may include a command CMD and an address ADDR. In some embodiments, the memory controller 120 may further provide clock signals to the memory device 110, and provides the command CMD and the address ADDR to the memory device 110 in synchronization with the clock signals to control the operation of the memory device 110.

In some embodiments, the memory controller 120 may provide the command CMD and the address ADDR to the memory device 110 to access the memory cell array 111 and control the memory operations such as read or write. The data may be transmitted to the memory controller 120 from the memory cell array 111 according to the read operation, and the data may be transmitted to the memory cell array 111 from the memory controller 120 according to the write operation.

The command CMD may include an activate command, read/write commands, a refresh command, and a precharge command. The activate command may switch a target row of the memory cell array 111 into an active state to write data to the memory cell array 111 or read data from the memory cell array 111. The memory cell of the target row may be activated (e.g., driven) in response to the activate command. The read/write command may perform a read operation or a write operation on the target memory cell of the row switched into the active state. The refresh command may perform a refresh operation on the memory cell array 111. In some embodiments, the refresh control circuit 112 may output a normal refresh command or a target row refresh (TRR) command in response to the refresh command. The TRR command may indicate an operation for refreshing the victim row. The normal refresh command may indicate a normal refresh operation, e.g., an operation for sequentially refreshing the rows of the memory cell array 111.

In some embodiments, the memory controller 120 may access the memory device 110 according to a request from a host outside the memory system 100. The memory controller 120 may communicate with the host by using various protocols.

The memory device 110 may be a storage device on the basis of the semiconductor device. In some embodiments, the memory device 110 may include a dynamic random access memory (DRAM). For example, the memory device 110 may be a double data rate synchronous dynamic random access memory (DDR SDRAM), a low power double data rate (LPDDR) SDRAM, a graphics double data rate (GDDR) SDRAM, and a Rambus dynamic random access memory (RDRAM).

In some embodiments, the memory device 110 may include another volatile or nonvolatile memory device using the refresh operation.

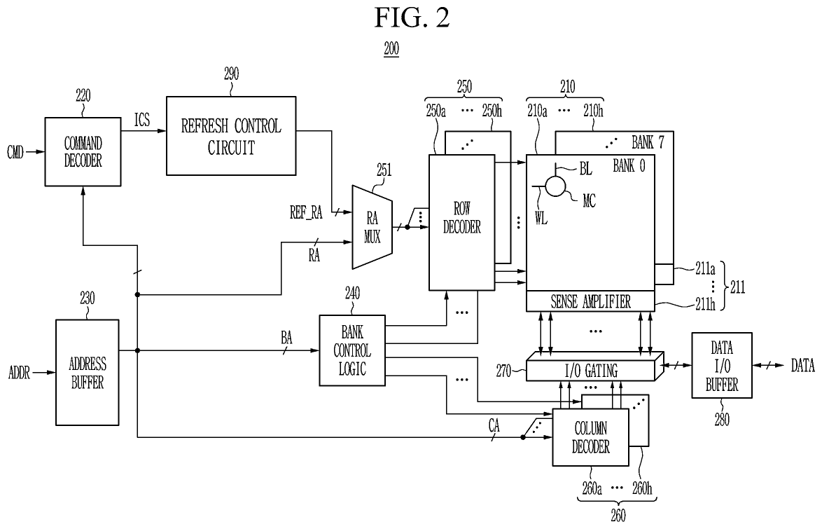

FIG. 2 shows a block diagram of a memory device according to an embodiment.

Referring to FIG. 2, a memory device 200 according to an embodiment may include a memory cell array 210, a sense amplifier 211, a command decoder (or a control logic circuit) 220, an address buffer 230, a row decoder 250, a column decoder 260, an input/output (I/O) gating circuit 270, a data I/O buffer 280, and a refresh control circuit 290.

The memory cell array 210 may include a plurality of memory cells MC. In some embodiments, the memory cell array 210 may include a plurality of memory banks 210a to 210h. FIG. 2 shows eight memory banks (BANK0 to BANK7) 210a to 210h, and the number of the memory banks is not limited thereto. The respective memory banks 210a to 210h may include a plurality of rows, a plurality of columns, and a plurality of memory cells MC arranged at corresponding intersections of the plurality of rows and the plurality of columns. In some embodiments, the plurality of rows may be defined by a plurality of word lines WL, and the plurality of columns may be defined by a plurality of bit lines BL.

The command decoder 220 may generate control signals so that the memory device 200 may perform a read operation, a write operation, or a refresh operation. The command decoder 220 may generate an internal command signal ICS by decoding the command CMD received from the memory controller (e.g., 120 of FIG. 1). The internal command signal ICS may include an active signal, a precharge signal, a refresh signal, a program signal, an erase signal, and a read signal. The active signal may correspond to the activate command of the memory controller 120. In some embodiments, the activate command of the memory controller 120 may also be directly provided to the refresh control circuit 290. The refresh signal may include the normal refresh command, the TRR command, etc. According to an embodiment, the command decoder 220 may also output the control signal to other components (e.g., the row decoder 250, etc.,) of the memory device 200.

The address buffer 230 may receive an address ADDR provided from the memory controller 120. The address ADDR may include a row address RA indicating the row of the memory cell array 210 and a column address CA indicating the column thereof. The row address RA may be provided to the row decoder 250, and the column address CA may be provided to the column decoder 260. The row address RA may be provided to the refresh control circuit 290 through the command decoder 220 or may be directly provided to the refresh control circuit 290. In some embodiments, the row address RA may be provided to the row decoder 250 through a row address multiplexer (RA MUX) 251. In some embodiments, the address ADDR may further include a bank address BA indicating the memory bank.

In some embodiments, the memory device 200 may further include the row address multiplexer 251. The row address multiplexer 251 may receive the row address RA from the address buffer 230, and may receive a row address REF_RA to be refreshed from the refresh control circuit 290. The row address multiplexer 251 may selectively output the row address RA received from the address buffer 230 and the row address REF_RA received from the refresh control circuit 290 to the row decoder 250. In some embodiments, the row address multiplexer 251 may output the row address REF_RA to be refreshed in response to the internal command signal ICS (e.g., a refresh signal) of the command decoder 220.

FIG. 2 shows that the command decoder 220 and the address buffer 230 are individual components, and without being limited thereto, the command decoder 220 and the address buffer 230 may also be realized into an inseparable component.

The row decoder 250 may select the row to be activated from among the plurality of rows of the memory cell array 210 based on the row address RA or REF_RA. For this purpose, the row decoder 250 may apply a driving voltage to the word line that corresponds to the row to be activated. In some embodiments, a plurality of respectively corresponding row decoders 250a to 250h may be provided to the plurality of memory banks 210a to 210h.

The column decoder 260 may select the column to be activated from among the plurality of columns of the memory cell array 210 based on the column address. For this purpose, the column decoder 260 may activate the sense amplifier 211 that corresponds to the column address CA through the I/O gating circuit 270. In some embodiments, a plurality of respectively corresponding column decoders 260a to 260h may be provided to the plurality of memory banks 210a to 210h. In some embodiments, the I/O gating circuit 270 may gate input/output data, and may include a data latch for storing the data read from the memory cell array 210 and a write driver for writing data to the memory cell array 210. The data read from the memory cell array 210 may be sensed by the sense amplifier 211, and may be stored in the I/O gating circuit 270 (e.g., a data latch). In some embodiments, a plurality of respectively corresponding sense amplifiers 211a to 211h may be provided to the plurality of memory banks 210a to 210h.

In some embodiments, the memory device 200 may further include a bank control logic 240 for generating a bank control signal in response to the bank address BA. In response to the bank control signal, the row decoder 250 that corresponds to the bank address BA from among the plurality of row decoders 250a to 250h may be activated, and the column decoder 260 that corresponds to the bank address BA from among the plurality of column decoders 260a to 260h may be activated. The activated row decoder may apply the driving voltage to the word line that corresponds to the row to be activated.

In some embodiments, the data (e.g., the data stored in the data latch) read from the memory cell array 210 may be provided to the memory controller 120 through the data I/O buffer 280. The data to be written to the memory cell array 210 may be provided to the data I/O buffer 280 from the memory controller 120, and the data provided to the data I/O buffer 280 may be provided to the I/O gating circuit 270.

The memory controller 120 may periodically transmit the command CMD relating to the refresh to the memory device 110. The refresh control circuit 290 may schedule the refresh based on the command CMD. The process for the refresh control circuit 290 to schedule the refresh may be understood as a process for determining a ratio of the normal refresh to the TRR, and periodically generating the normal refresh command and the TRR command based on the determined ratio.

The refresh control circuit 290 may transmit the row address REF_RA to be refreshed to the row decoder 250 in response to the refresh signal from among the internal command signal ICS. In some embodiments, the row address REF_RA may indicate the row address of the normal refresh or the victim row address of the target row refresh.

The refresh control circuit 290 may output the victim row address in response to the TRR command from among the internal command signal ICS. In some embodiments, the TRR command may be a row hammer refresh command.

The refresh control circuit 290 may determine the refresh address so that the victim row address may not be repeatedly refreshed. For example, the refresh control circuit 290 may determine the aggressor row address in response to the activate command of the memory controller or the active signal from among the internal command signal ICS. The refresh control circuit 290 may determine a difference between the currently determined aggressor row address and the previous aggressor row address. The refresh control circuit 290 may replace the victim row address with another row address based on the difference of the aggressor row addresses (i.e., the currently determined aggressor row address and the previous aggressor row address) or may skip the refresh of the victim row address. Hence, the memory device 200 may increase defense performance and may reduce power consumption.

In some embodiments, the refresh control circuit 290 may output the row address that becomes the target of the normal refresh in response to the normal refresh command of the internal command signal ICS. The refresh control circuit 290 may calculate the row address for performing a normal refresh operation, and may output the row address in response to the normal refresh command. The refresh control circuit 290 may sequentially increase/reduce the row address each time the normal refresh operation is performed.

In some embodiments, the refresh control circuit 290 may output the row address of the normal refresh as the row address REF_RA in response to the normal refresh command, and may output the victim row address as the row address REF_RA in response to the TRR command. In some embodiments, the refresh control circuit 290 may randomly generate the TRR command or the normal refresh command in response to the refresh signal. In some embodiments, the refresh control circuit 290 may generate the TRR command or the normal refresh command based on a predetermined refresh ratio in response to the refresh signal.

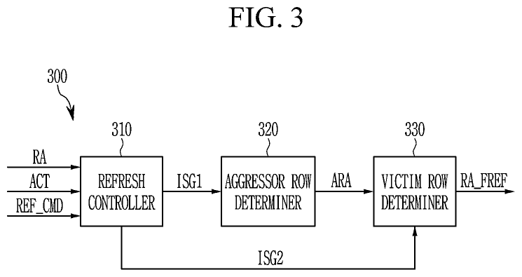

FIG. 3 shows a block diagram of a refresh control circuit 300 according to an embodiment.

Referring to FIG. 3, the refresh control circuit 300 according to an embodiment may generate a refresh address RA_FREF to be used to a target row refresh. The refresh control circuit 300 may include a refresh controller 310, an aggressor row determiner 320, and a victim row determiner 330. In an embodiment, the refresh control circuit 300 of FIG. 3 may correspond to the refresh control circuit 290 of FIG. 2. In an embodiment, the refresh control circuit 290 may include the refresh control circuit 300 of FIG. 3. For example, the refresh control circuit 290 may output the row address REF_RA by using the refresh address RA_FREF of FIG. 3.

The refresh controller 310 may receive an active signal ACT, a row address RA that corresponds to the active signal ACT, and a refresh command REF_CMD. The refresh controller 310 may generate internal signals ISG1 and ISG2 based on the active signal ACT, the row address RA, and the refresh command REF_CMD.

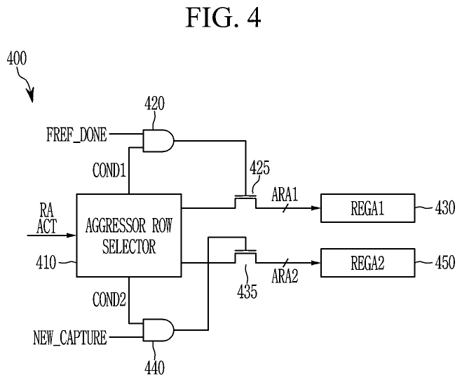

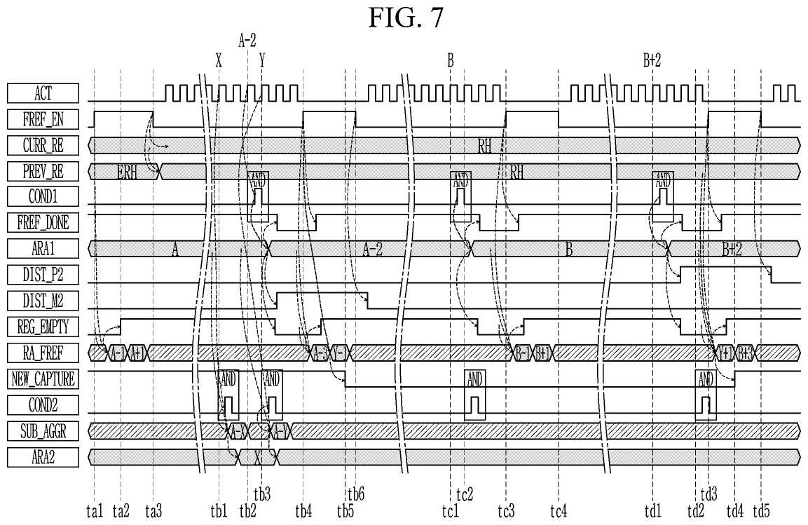

The internal signal ISG1 may include a refreshed signal, a row selecting signal, the active signal ACT, the row address RA, and a target row refresh signal (e.g., FREF_EN of FIG. 7). The internal signal ISG2 may include a victim row switch signal, the row selecting signal, a difference signal, and a row gap signal. The internal signal ISG1 and the internal signal ISG2 will be described later with reference to FIG. 4 to FIG. 9. The refresh controller 310 may transmit the internal signal ISG1 to the aggressor row determiner 320, and may transmit the internal signal ISG2 to the victim row determiner 330. According to an embodiment, the internal signal ISG1 and the internal signal ISG2 may also include at least one signal in common.

The aggressor row determiner 320 may determine the aggressor row address ARA based on the internal signal ISG1. In an embodiment, the aggressor row determiner 320 may generate a random number based on the internal signal ISG1, and may determine whether to determine the row address RA as an aggressor row address ARA based on the random number. In another embodiment, the aggressor row determiner 320 may count the activating number of the row address RA based on the active signal ACT and the row address RA. For example, the aggressor row determiner 320 may count the activating number of the row address RA in one target row refresh section (i.e., a section from one target row refresh time to the next target row refresh time). The aggressor row determiner 320 may determine the aggressor row address ARA based on the activating number. For example, the aggressor row determiner 320 may determine the row address RA with the greatest activating number as the aggressor row address ARA. The method for the aggressor row determiner 320 to determine the aggressor row address ARA is not specifically limited, and may be realized in many ways. The aggressor row determiner 320 may transmit the aggressor row address ARA to the victim row determiner 330.

The victim row determiner 330 may determine a plurality of victim row addresses based on the aggressor row address ARA. The victim row determiner 330 may determine one of the plurality of victim row addresses as the refresh address RA_FREF based on the internal signal ISG2. The memory device may perform a refresh based on the refresh address RA_FREF.

The victim row determiner 330 may determine the refresh address RA_FREF so that the previously refreshed victim row address may not be repeatedly refreshed. Herein, the refreshed row address may mean that memory cells connected to a row corresponding to the row address are refreshed. For example, the victim row determiner 330 may determine whether the difference between the previous aggressor row address ARA and the current aggressor row address ARA is 2. When the difference therebetween is 2, the victim row determiner 330 may replace the victim row address with another row address and refresh the same based on the previous aggressor row address. Hence, defense performance of the memory device including the refresh control circuit 300 may be increased.

A configuration for the aggressor row determiner 320 and the victim row determiner 330 to determine the addresses ARA and RA_FRER will be described later with reference to FIG. 4 to FIG. 9.

FIG. 4 shows a block diagram of an aggressor row determiner 400 according to an embodiment.

Referring to FIG. 4, the aggressor row determiner 400 according to an embodiment may determine the aggressor row addresses ARA1 and ARA2 based on the internal signal (e.g., ISG1 of FIG. 3). The internal signal may include a refreshed signal FREF_DONE, a row selecting signal NEW_CAPTURE, an active signal ACT, and a row address RA. In some embodiments, the active signal ACT and the row address RA may also be directly received from the memory controller (e.g., 120 of FIG. 1).

The aggressor row determiner 400 may include an aggressor row selector 410, AND gates 420 and 440, transistors 425 and 435, and registers (REGA1 and REGA2) 430 and 450. In some embodiments, the registers 430 and 450 may also be realized to be arranged outside the aggressor row determiner 400. In an embodiment, the aggressor row determiner 400 of FIG. 4 may correspond to the aggressor row determiner 320 of FIG. 3.

The aggressor row selector 410 may receive the active signal ACT and the row address RA. When receiving the active signal ACT, the aggressor row selector 410 may determine the aggressor row addresses ARA1 and ARA2 based on the row address RA.

The aggressor row selector 410 may generate a random number when receiving the active signal ACT. For example, the aggressor row selector 410 may include a random number generator. According to an embodiment, the random number generator may be a true random number generator (TRNG) or a pseudo random number generator (PRNG). That is, the random number may be a true random number or a pseudo random number. In an embodiment, when the random number generator is a PRNG, the random number generator may be realized with a linear feedback shift register (LFSR). In an embodiment, the random number generator may generate random numbers that are real number in the range of 0 to 1. In an embodiment, the random number generator may generate random numbers that are integers in the range of 0 to a maximum value. In an embodiment, when the random number generator is an n-bit LFSR, the maximum value may be 2ⁿ-1 (here, n is an integer that is greater than 1).

The aggressor row selector 410 may determine the aggressor row addresses ARA1 and ARA2 based on the generated random number. For example, the aggressor row selector 410 may generate a first condition signal COND1 of a first level (e.g., a logical high level) when the random number value is in a first range. Hereinafter, the first level may be referred to as a logical high level. The aggressor row selector 410 may generate a second condition signal COND2 of the first level when the value of the random number is in a second range. In some embodiments, the aggressor row selector 410 may not generate the signals when the value of the random number is not in the first range and the second range. In this case, the row address RA may not be determined as any of the aggressor row addresses ARA1 and ARA2.

The aggressor row selector 410 may output the first condition signal COND1 and the second condition signal COND2 at different times. For example, the aggressor row selector 410 may output the first condition signal COND1 of the first level at the first time. In this instance, when the refreshed signal FREF_DONE is on the first level, the aggressor row selector 410 may transmit the row address RA as the aggressor row address ARA1. The level of the refreshed signal FREF_DONE may be changed when the aggressor row address ARA1 is output. For example, the refreshed signal FREF_DONE may be changed to a second level (e.g., a logical low level) from the first level. Hereinafter, the second level may be referred to as a logical low level. The refreshed signal FREF_DONE may be changed to the first level from the second level when a target row refresh is performed.

The aggressor row selector 410 may output the second condition signal COND2 of the first level at the second time. In this instance, the aggressor row selector 410 may transmit the row address RA as the aggressor row address ARA2 when the row selecting signal NEW_CAPTURE is on the first level. The level of the row selecting signal NEW_CAPTURE may be changed when the refresh is performed on one victim row based on the aggressor row address ARA2. For example, the row selecting signal NEW_CAPTURE may be changed to the second level from the first level. The level of the row selecting signal NEW_CAPTURE may be changed to the first level from the second level when the refresh is performed on the other victim row at the next time.

The AND gate 420 may receive the refreshed signal FREF_DONE and the first condition signal COND1. The AND gate 420 may perform an AND operation on the refreshed signal FREF_DONE and the first condition signal COND1, and may transmit an operation result to the transistor 425.

The AND gate 420 may output an operation result of the first level when the refreshed signal FREF_DONE and the first condition signal COND1 are on the first level. The AND gate 420 may output an operation result of the second level when at least one of the refreshed signal FREF_DONE and the first condition signal COND1 is on the second level.

The AND gate 440 may receive the row selecting signal NEW_CAPTURE and the second condition signal COND2. The AND gate 440 may perform an AND operation on the row selecting signal NEW_CAPTURE and the second condition signal COND2, and may transmit an operation result to the transistor 435.

The AND gate 440 may output an operation result of the first level when the row selecting signal NEW_CAPTURE and the second condition signal COND2 are on the first level. The AND gate 440 may output an operation result of the second level when at least one of the row selecting signal NEW_CAPTURE and the second condition signal COND2 is on the second level.

The transistors 425 and 435 according to an embodiment may be realized with a metal oxide silicon (or semiconductor) field effect transistor (MOSFET). According to an embodiment, each of the transistors 425 and 435 may be realized with a p-channel or an n-channel transistor.

The transistor 425 may receive an operation result from the AND gate 420 through a gate of the transistor 425 and may be operated based on the operation result of the AND gate 420, and the transistor 435 may receive an operation result from the AND gate 440 through a gate of the transistor 435 and may be operated based on the operation result of the AND gate 440. For example, when receiving the operation result of the first level, the transistors 425 and 435 may be turned on and may transmit the row address RA of the aggressor row selector 410 to the registers 430 and 450 as the aggressor row addresses ARA1 and ARA2. The row address RA may include a plurality of bits. The registers 430 and 450 may receive the aggressor row addresses ARA1 and ARA2 and may store them.

The transistors 425 and 435 may receive the operation result of the second level and may be turned off. For example, when receiving the row address RA, the transistors 425 and 435 may not transmit the row address RA to the registers 430 and 450 based on the operation results of the second level.

In some embodiments, the registers 430 and 450 may output the aggressor row addresses ARA1 and ARA2 in response to the target row refresh signal of the first level.

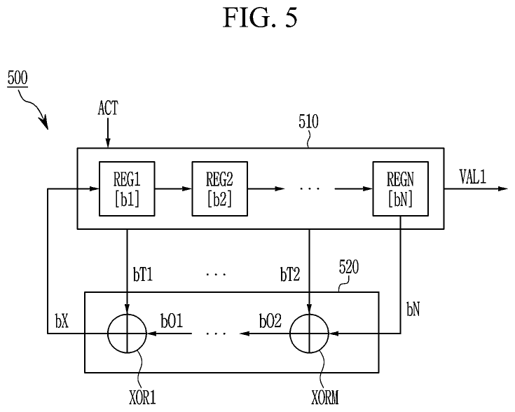

FIG. 5 shows a block diagram of a linear feedback shift register (LFSR) 500 according to an embodiment.

Referring to FIG. 5, the linear feedback shift register 500 according to an embodiment may include a register circuit 510 and a logic operation circuit 520. The linear feedback shift register 500 may be understood as a random bit generator or a random number generator. For example, the aggressor row selector 410 may include the linear feedback shift register 500.

The linear feedback shift register 500 may determine a feedback bit based on a characteristic polynomial with a coefficient of 0 or 1. The register circuit 510 and the logic operation circuit 520 of the linear feedback shift register 500 may be designed based on the characteristic polynomial. For example, when the characteristic polynomial is x¹⁰+x⁷+x²+1, the register circuit 510 may include first to tenth registers, and the logic operation circuit 520 may include first and second logic circuits. For example, N may be 10 and M may be 2 in FIG. 5. The first to tenth registers and the first and second logic circuits may be connected to satisfy the characteristic polynomial. Outputs of the seventh and tenth registers from among the first to tenth registers may be transmitted to the second logic circuit, and an output of the second logic circuit and an output of the second register may be transmitted to the first logic circuit. An output of the first logic circuit may be transmitted to the first register.

The register circuit 510 may output feedback bits bT1 . . . , bT2, and bN based on input bits. The register circuit 510 may output the feedback bits bT1 . . . , bT2, and bN to a feedback path of the linear feedback shift register 500. The logic operation circuit 520 may perform a logic operation based on the feedback bits bT1 . . . , bT2, and bN and may generate operation bits bO1 . . . , bO2, and bX. The operation bit bX finally generated by the logic operation circuit 520 is an input bit and may be input to the register circuit 510. The linear feedback shift register 500 may generate a pseudo random number sequence by performing a shift operation based on the bit input to the input end.

The register circuit 510 may include first to N-th registers REG1 to REGN (N is an integer that is greater than 1). The first to N-th registers REG1 to REGN may respectively store first to N-th bits b1 to bN. Bit values of the first to N-th bits b1 to bN may be changed according to a shift operation.

The logic operation circuit 520 may receive the feedback bits bT1 . . . , bT2, and bN from the register circuit 510, and may perform a logic operation based on the feedback bits bT1 . . . , bT2, and bN. The logic operation circuit 520 may include first to the M-th logic circuits XOR1 to XORM (M is an integer greater than 1). The first to the M-th logic circuits XOR1 to XORM may perform an XOR operation.

An output end of the M-th logic circuit XORM may be connected to the (M−1)th logic circuit, and the first logic circuit XOR1 may be connected to an output end of the second logic circuit. For example, the first logic circuit XOR1 from among the first to M-th logic circuits XOR1 to XORM may finally perform an operation and an operation result of the first logic circuit XOR1 may be input to the first register REG1 of the register circuit 510.

The first to the M-th logic circuits XOR1 to XORM may be connected along the feedback path, and may transmit an operation result to the logic circuit of the previous end. For example, the M-th logic circuit XORM may be connected to an output end of the N-th register REGN. The M-th logic circuit XORM may be further connected to an output end of one of the first to (N−1)th registers. The output end of the (N−1)th register may be connected to the N-th register REGN.

The M-th logic circuit XORM may receive the feedback bit bN from the N-th register REGN, and may receive the feedback bit bT2 from one of the first to (N−1)th registers. The M-th logic circuit XORM may perform a logic operation on the feedback bit bN and the feedback bit bT2 and may generate an operation bit bO2. The first logic circuit XOR1 may receive the operation bit bO1 from the logic circuit at a rear end, and may receive the feedback bit bT1 from one of the first to (N−1)th registers. The operation bit bO1 may be generated by the logic operation based on the operation bit bO2. The first logic circuit XOR1 may generate the operation bit bX by performing a logic operation on the operation bit bO1 and the feedback bit bT1. The first logic circuit XOR1 may transmit the operation bit bX to the first register REG1.

The first register REG1 may store the operation bit bX input through the feedback path as the first bit b1. The bit input through the feedback path may be shifted through the first to N-th registers REG1 to REGN based on the control signal.

The linear feedback shift register 500 may output a first value VAL1 that is a random number through the register circuit 510. The linear feedback shift register 500 may output the first value VAL1 when receiving the active signal ACT. The first value VAL1 may be a random binary code having a predetermined number of bits. For example, the linear feedback shift register 500 may output random binary codes that have N-numbered bits based on the first to N-th bits b1 to bN stored in the first to N-th registers REG1 to REGN.

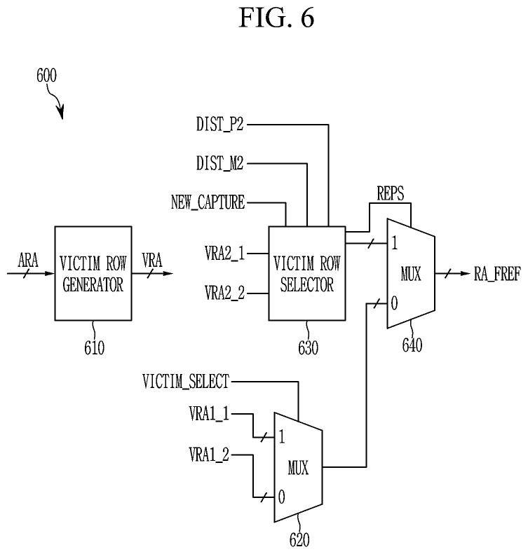

FIG. 6 shows a block diagram of a victim row determiner 600 according to an embodiment.

Referring to FIG. 6, the victim row determiner 600 according to an embodiment may generate a victim row address VRA based on the aggressor row address ARA, and may generate a refresh address RA_FREF based on the victim row address VRA. The aggressor row address ARA may include an aggressor row address ARA1 of the first register (e.g., 430 of FIG. 4), and an aggressor row address ARA2 of the second register (e.g., 450 of FIG. 4). The victim row address VRA may include victim row addresses VRA1_1, VRA1_2, VRA2_1, and VRA2_2.

The victim row determiner 600 may include a victim row generator 610, a first multiplexer 620, a victim row selector 630, and a second multiplexer 640. In an embodiment, the victim row determiner 600 of FIG. 6 may correspond to the victim row determiner 330 of FIG. 3.

The victim row generator 610 may generate a victim row address VRA based on the aggressor row address ARA. For example, the victim row generator 610 may generate the victim row address VRA. A victim row (or a victim word line) corresponding to the victim row address VRA that is disposed near an aggressor row (or an attack row) corresponding to the aggressor row address ARA. A physical position difference between the victim row and the aggressor row may be 1. In some embodiments, the victim row generator 610 may receive a control signal from the refresh controller 310 of FIG. 3, and may also generate the victim row address VRA of which the physical position difference between the victim row and the aggressor row is equal to or greater than 2 based on the control signal.

The victim row generator 610 may generate the victim row addresses VRA1_1 and VRA1_2 based on the aggressor row address ARA1 of FIG. 4. The victim row generator 610 may generate the victim row addresses VRA2_1 and VRA2_2 based on the aggressor row address ARA2 of FIG. 4. In some embodiments, the victim row generator 610 may also be respectively realized with two generators for receiving the aggressor row addresses ARA1 and ARA2 and generating the victim row addresses VRA1_1, VRA1_2, VRA2_1, and VRA2_2.

The first multiplexer 620 may receive the victim row addresses VRA1_1 and VRA1_2 from the victim row generator 610, and may receive the victim row switch signal VICTIM_SELECT from the refresh controller 310. The first multiplexer 620 may transmit one of the victim row addresses VRA1_1 and VRA1_2 to the second multiplexer 640 based on the victim row switch signal VICTIM_SELECT.

The refresh controller 310 may change the level of the victim row switch signal VICTIM_SELECT when the row corresponding to one of the victim row addresses VRA1_1 and VRA1_2 is refreshed. For example, the first multiplexer 620 may transmit the victim row address VRA1_2 to the second multiplexer 640 based on the victim row switch signal VICTIM_SELECT of the second level. When the row corresponding to the victim row address VRA1_2 as the refresh address RA_FREF is refreshed, the refresh controller 310 may output the victim row switch signal VICTIM_SELECT of the first level. The first multiplexer 620 may transmit the victim row address VRA1_1 to the second multiplexer 640 based on the victim row switch signal VICTIM_SELECT of the first level. When the row corresponding to the victim row address VRA1_1 as the refresh address RA_FREF is refreshed, the refresh controller 310 may output the victim row switch signal VICTIM_SELECT of the second level.

The victim row selector 630 may receive the victim row addresses VRA2_1 and VRA2_2 from the victim row generator 610, and may receive the row selecting signal NEW_CAPTURE and difference signals DIST_P2 and DIST_M2 from the refresh controller 310.

The victim row selector 630 may transmit one of the victim row addresses VRA2_1 and VRA2_2 to the second multiplexer 640 based on the row selecting signal NEW_CAPTURE and the difference signals DIST_P2 and DIST_M2. For example, the victim row selector 630 may transmit the victim row address VRA2_1 to the second multiplexer 640 based on the row selecting signal NEW_CAPTURE of the first level and the difference signal DIST_P2 of the first level. The victim row selector 630 may transmit the victim row address VRA2_2 to the second multiplexer 640 based on the row selecting signal NEW_CAPTURE of the first level and the difference signal DIST_M2 of the first level.

The refresh controller 310 may change the level of the row selecting signal NEW_CAPTURE when the row corresponding to one (e.g., VRA2_2) of the victim row addresses VRA2_1 and VRA2_2 is refreshed. For example, the refresh controller 310 may change the row selecting signal NEW_CAPTURE of the first level to the second level when the row corresponding to the victim row addresses VRA2_2 is refreshed. The refresh controller 310 may change the row selecting signal NEW_CAPTURE of the second level to the first level when the row corresponding to the other (e.g., VRA2_1) of the victim row addresses VRA2_1 and VRA2_2 is refreshed.

The refresh controller 310 may calculate the difference between rows corresponding to the previous aggressor row address ARA1 and the current aggressor row address ARA1. For example, the refresh controller 310 may include a subtractor. The subtractor may output a difference signal DIST_P2 of the first level when the row corresponding to the current aggressor row address ARA1 is greater than the row corresponding to the previous aggressor row address ARA1 by the value of 2. In this case, the row corresponding to the current aggressor row address ARA1 is disposed above and spaced from the row corresponding to the previous aggressor row address ARA1 by 2. For example, one row is disposed below the row corresponding to the current aggressor row address ARA1 and above the row corresponding to the previous aggressor row address ARA1. The subtractor may output the difference signal DIST_M2 of the first level when the row corresponding to the current aggressor row address ARA1 is less than the row corresponding to the previous aggressor row address ARA1 by the value of 2. In this case, the row corresponding to the current aggressor row address ARA1 is disposed below and spaced from the row corresponding to the previous aggressor row address ARA1 by 2. For example, one row is disposed above the row corresponding to the current aggressor row address ARA1 and below the row corresponding to the previous aggressor row address ARA1.

The refresh controller 310 may change the difference signal DIST_P2 or DIST_M2 of the first level to the second level when the target row refresh signal FREF_EN become the second level from the first level.

The victim row selector 630 may generate a replaced switch signal REPS based on the difference signals DIST_P2 and DIST_M2. The victim row selector 630 may include an OR gate. The OR gate may perform an OR operation on the difference signals DIST_P2 and DIST_M2. For example, the OR gate may output a high level when one of the difference signals DIST_P2 and DIST_M2 is high level (e.g., the first level), and it may output a low level when the difference signals DIST_P2 and DIST_M2 are low level (e.g., the second level).

The victim row selector 630 may delay the replaced switch signal REPS and may output when the difference signal DIST_M2 is the high level. For example, the victim row selector 630 may generate the replaced switch signal REPS so that the victim row address VRA2_2 may be output as the refresh address RA_FREF after the victim row address VRA1_2 is output as the refresh address RA_FREF. When the difference signal DIST_P2 is the high level, the victim row selector 630 may generate a replaced switch signal REPS so that the victim row address VRA1_1 may be output as the refresh address RA_FREF after the victim row address VRA2_1 is output as the refresh address RA_FREF. The victim row selector 630 may transmit the replaced switch signal REPS to the second multiplexer 640.

The second multiplexer 640 may output the refresh address RA_FREF based on the replaced switch signal REPS. For example, the second multiplexer 640 may receive the replaced switch signal REPS of the second level and may output an address from the first multiplexer 620 as the refresh address RA_FREF. The second multiplexer 640 may receive the replaced switch signal REPS of the first level and may output an address from the victim row selector 630 as the refresh address RA_FREF.

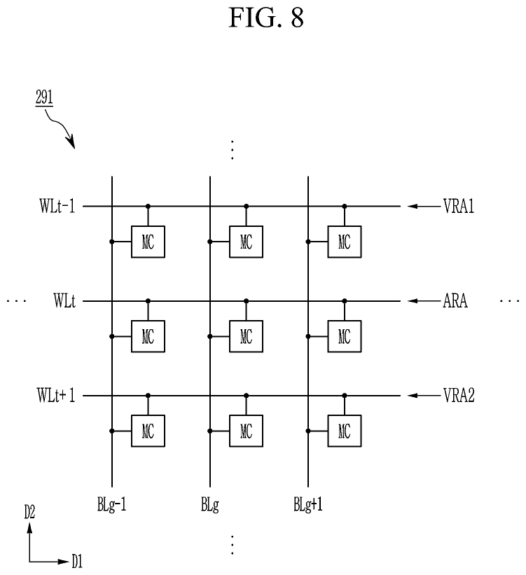

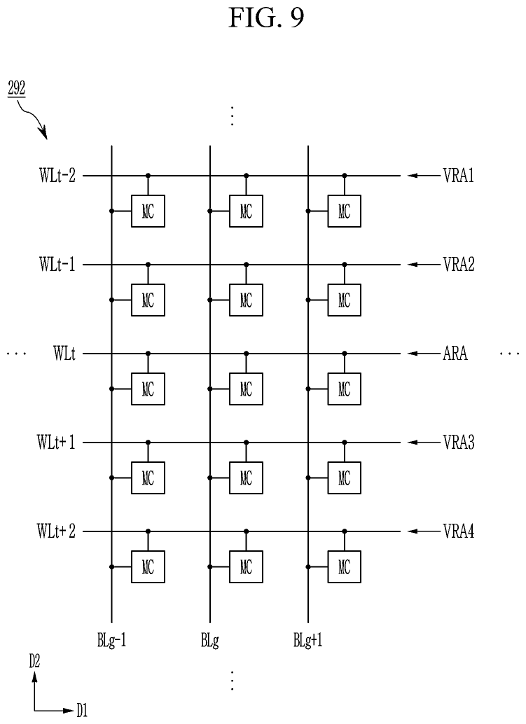

FIG. 7 shows a timing diagram illustrating a refresh operation of a memory device according to an embodiment, and FIG. 8 and FIG. 9 show a portion of a memory cell array of a memory device.

Referring to FIG. 7, the memory device according to an embodiment may receive commands (e.g., an activate command ACT, a refresh command, etc.,) from the memory controller.

The memory device may generate internal signals based on the command of the memory controller. The internal signals may include the target row refresh signal FREF_EN, row gap signals CURR_RE and PREV_RE, a first condition signal COND1, a refreshed signal FREF_DONE, difference signals DIST_P2 and DIST_M2, a register signal REG_EMPTY, a row selecting signal NEW_CAPTURE, a second condition signal COND2, a difference value signal SUB_AGGR, a victim row switch signal VICTIM_SELECT of FIG. 6, etc. The register signal REG_EMPTY may indicate whether the first register (e.g., 430 of FIG. 4) stores the aggressor row address. The difference value signal SUB_AGGR may show the difference value between the aggressor row address ARA1 and the row address corresponding to being received the activate command ACT. For example, the difference value signal SUB_AGGR may show the difference value between a row corresponding to the aggressor row address ARA1 and a row corresponding to the row address corresponding to being received the activate command ACT.

The memory device may determine the aggressor row addresses ARA1 and ARA2 based on the command of the memory controller and the internal signal. The memory device may determine the victim row address based on the aggressor row addresses ARA1 and ARA2, and may output one of the victim row addresses as the refresh address RA_FREF. The memory device may perform a target row refresh operation by using the refresh address RA_FREF.

The memory device may generate row gap signals CURR_RE and PREV_RE. The row gap signals CURR_RE and PREV_RE may indicate to determine the row that is distant from the determined aggressor row address ARA1 or ARA2 by a predetermined gap as the victim row.

The row gap signal CURR_RE may indicate how far the row corresponding to the victim row address to be currently refreshed is from the row corresponding to the aggressor row address ARA1 or ARA2. The row gap signal PREV_RE may indicate how far the row corresponding to the previously refreshed victim row address is from the row corresponding to previously determined aggressor row address. The victim row generator (e.g., 610 of FIG. 6) may determine the victim row address based on the row gap signal CURR_RE.

For example, when the row gap signal CURR_RE indicates ‘RH’, the victim row generator may indicate the rows of ±1 with respect to the aggressor row address ARA1 or ARA2. When the row gap signal CURR_RE indicates ‘ERH’, the victim row generator may indicate the rows of ±2 with respect to the aggressor row address ARA1 or ARA2. However, without being limited thereto, the memory device may indicate the rows of ±p (p is an integer that is greater than 2) with respect to the aggressor row address ARA1 or ARA2.

Referring to FIG. 8, the memory cell array 291 includes three word lines WLt−1, WLt, and WLt+1 extending in the row direction (or the first direction) D1 and sequentially arranged near each other in the column direction (or the second direction) D2; three bit lines BLg−1, BLg, and BLg+1 extending in the column direction D2 and sequentially arranged near each other in the row direction D1; and memory cells MC respectively combined thereto.

In this instance, the word line WLt from among the word lines WLt−1, WLt, and WLt+1 may correspond to the frequently accessed aggressor row address ARA. Here, the term of frequently accessed represents that the number of activating the word lines is great or the activating frequency is great. For example, the number of activating a particular word line (e.g., WLt) is equal to or greater than a reference value during a predetermined time period. The word line WLt may be referred to as a hammer word line. When the word line WLt is accessed to be activated and precharged, that is, a voltage of the word line WLt is increased and reduced, the voltages of the adjacent word lines WLt−1 and WLt+1 may rise and fall because of a coupling phenomenon generated between the adjacent word lines WLt−1 and WLt+1 and an influence may be applied to cell charges stored in the memory cells MC connected to the adjacent word lines WLt−1 and WLt+1. When the word line WLt is frequently accessed, the cell charges in the memory cells MC connected to the victim word lines WLt−1 and WLt+1 may be lost and the stored data may be damaged.

By using the row gap signals CURR_RE and PREV_RE for indicating ‘RH’, the memory device of FIG. 7 may provide the addresses VRA1 and VRA2 of the word lines WLt−1 and WLt+1 disposed physically near the word line WLt that corresponds to the aggressor row address ARA. That is, the memory device may prevent data damages of the memory cells caused by the frequent access by performing a refresh operation on the adjacent word lines WLt−1 and WLt+1 based on the victim row address.

Referring to FIG. 9, the memory cell array 292 includes: five word lines WLt−2, WLt−1, WLt, WLt+1, and WLt+2 extending in the row direction D1 and sequentially arranged near each other in the column direction D2; three bit lines BLg−1, BLg, and BLg+1 extending in the column direction D2 and sequentially arranged near each other in the row direction D1; and memory cells MC respectively combined thereto. In this instance, the word line WLt from among the word lines WLt−2, WLt−1, WLt, WLt+1, and WLt+2 may correspond to the frequently accessed aggressor row address ARA.

By using the row gap signals CURR_RE and PREV_RE for indicating ‘RH’, the memory device of FIG. 7 may provide the addresses VRA2 and VRA3 of the word lines WLt−1 and WLt+1 disposed physically near the word line WLt that corresponds to the aggressor row address ARA. By using the row gap signals CURR_RE and PREV_RE indicating ‘ERH’, the memory device may provide addresses VRA1 and VRA4 of the word lines WLt−2 and WLt+2 disposed physically near the word line WLt that corresponds to the aggressor row address ARA. For example, the memory device may prevent data damages of the memory cells caused by the frequent access by performing a refresh operation on the adjacent word lines WLt−1, WLt+1, WLt−2, and WLt+2 based on the victim row address.

Referring to FIG. 7, the memory device may transition the level of the target row refresh signal FREF_EN to High from Low at a time ta1. For example, the memory device may generate a target row refresh signal FREF_EN in response to the refresh command of the memory controller.

The first register (e.g., 430 of FIG. 4) of the memory device may store ‘A’ as the aggressor row address ARA1 at the time ta1. When the first register stores the aggressor row address ARA1, the register signal REG_EMPTY may be on the low level. The first register may output the aggressor row address ARA1 of ‘A’ in response to the target row refresh signal FREF_EN on the high level, and may transition the level of the register signal REG_EMPTY to High at a time ta2.

The victim row generator (e.g., 610 of FIG. 6) of the victim row determiner (e.g., 600 of FIG. 6) may receive the aggressor row address ARA1 and the row gap signal CURR_RE. The victim row generator may confirm that the row gap signal CURR_RE is ‘RH’, and may determine ‘A−1’ and ‘A+1’ as the victim row address.

The victim row determiner may output ‘A−1’ and ‘A+1’ as the refresh address RA_FREF. The victim row determiner may sequentially output ‘A−1’ and ‘A+1’ based on the victim row switch signal. FIG. 7 shows that the victim row determiner outputs ‘A−1’ and ‘A+1’, the embodiment is not limited thereto, and the victim row determiner may also be realized to output ‘A+1’ and ‘A−1’.

The memory device may transition the level of the target row refresh signal FREF_EN to Low from High at a time ta3. The memory device may store the row gap signal CURR_RE used at a first refresh of a time section (ta1 to ta3) as the row gap signal PREV_RE. For example, at the first refresh, the row gap signal CURR_RE may be ‘RH’, and the memory device may change the row gap signal PREV_RE to ‘RH’ at the time ta3. The memory device may determine the row gap signal CURR_RE to be used at the next refresh. For example, the memory device may maintain the row gap signal CURR_RE at ‘RH’ at the time ta3.

The memory device may complete the first refresh and may receive the activate command ACT.

The memory device may receive the activate command ACT and the row address X that corresponds thereto at a time tb1. The aggressor row selector (e.g., 410 of FIG. 4) of the memory device may generate the second condition signal COND2 on the high level based on the activate command ACT and the row address X at the time tb1. The refresh controller 310 may generate a difference value signal SUB_AGGR when the second condition signal COND2 and the row selecting signal NEW_CAPTURE are high level. The difference value signal SUB_AGGR may indicate a difference value between the aggressor row address ARA1 and the row address corresponding to being received the activate command ACT. For example, the subtractor of the refresh controller 310 may receive the aggressor row address ARA1 of ‘A’ and the row address of ‘X’, and may output a difference value A-X of the two addresses as the difference value signal SUB_AGGR. For example, the difference value A-X of the two row addresses may mean the difference value between the row corresponding to the aggressor row address ARA1 of ‘A’ and the row corresponding to the row address of ‘X’.

The aggressor row selector may determine whether the difference value signal SUB_AGGR is greater than a reference value (a number that is equal to or greater than 2). The reference value may be determined based on the current row gap signal and the previous row gap signal. In an embodiment, the aggressor row selector may determine whether the difference value signal SUB_AGGR is greater than 2. The aggressor row selector may determine the row address as the aggressor row address ARA2 when the difference value signal SUB_AGGR is greater than 2. The aggressor row selector may store the aggressor row address ARA2 in the second register (e.g., 450 of FIG. 4).

The memory device may receive the activate command ACT and a row address A−2 that corresponds to the same at the time tb2. The aggressor row selector may generate the first condition signal COND1 on the high level based on the activate command ACT and the row address A−2 at the time tb2. The aggressor row selector may maintain the condition signals COND1 and COND2 at the high level for a unit time. That is, the aggressor row selector may transition the condition signals COND1 and COND2 to the low level when the unit time passes. The aggressor row selector may determine the row address A−2 as the aggressor row address ARA1 when the first condition signal COND1 and the refreshed signal FREF_DONE are high level. The aggressor row selector may store the aggressor row address ARA1 in the first register.

The memory device may transition the refreshed signal FREF_DONE to the low level when the aggressor row address ARA1 of ‘A−2’ is stored in the first register. The memory device may transition the register signal REG_EMPTY to the low level when the aggressor row address ARA1 of ‘A−2’ is stored in the first register.

The memory device may calculate the difference value between the current aggressor row address ARA1 and the previous aggressor row address ARA1. For example, the memory device may calculate the difference between ‘A−2’ and ‘A’. For example, the memory device may calculate the difference between two rows corresponding to the row addresses ‘A−2’ and ‘A’. The row corresponding to the current aggressor row address ARA1 of ‘A−2’ is less than the row corresponding to the previous aggressor row address ARA1 of ‘A’ by 2 so the memory device may generate a difference signal DIST_M2 on the high level.

The memory device may receive the activate command ACT and a row address Y that corresponds to the same at the time tb3.

The aggressor row selector may generate a second condition signal COND2 on the high level based on the activate command ACT and the row address Y at the time tb3. The aggressor row selector may generate a difference value signal SUB_AGGR when the second condition signal COND2 and the row selecting signal NEW_CAPTURE are the high level. For example, the subtractor may output the difference value A−Y between the aggressor row address ARA1 of ‘A’ and the row address of ‘Y’ as the difference value signal SUB_AGGR. For example, the difference value A−Y may mean the difference value between the row corresponding to the aggressor row address ARA1 of ‘A’ and the row corresponding to the row address of ‘Y’.

The aggressor row selector may determine that the difference value signal SUB_AGGR is greater than 2, and may determine the row address as the aggressor row address ARA2. The aggressor row selector may change the aggressor row address ARA2 of the second register to ‘Y’.

The memory device may transition the level of the target row refresh signal FREF_EN to High from Low at a time tb4. The memory device may transition the refreshed signal FREF_DONE to the high level in response to the target row refresh signal FREF_EN on the high level.

The first register may output the aggressor row address ARA1 of ‘A−2’ in response to the target row refresh signal FREF_EN on the high level, and may transition the level of the register signal REG_EMPTY to High.

The memory device may operate the victim row determiner when the row gap signals CURR_RE and PREV_RE are ‘RH’. For example, the victim row determiner may not be operated when at least one of the row gap signals CURR_RE and PREV_RE is ‘ERH’.

The victim row generator of the victim row determiner may receive the aggressor row address ARA1 of ‘A−2’ and the row gap signal CURR_RE of ‘RH’. The victim row generator may determine ‘A−3’ and ‘A−1’ as the victim row address. The ‘A−3’ and ‘A−1’ generated by the victim row generator may be input to the first multiplexer (e.g., 620 of FIG. 6) of the victim row determiner. The first multiplexer may transmit the ‘A−3’ to the second multiplexer (e.g., 640 of FIG. 6) based on the victim row switch signal VICTIM_SELECT on the low level. The second multiplexer may output the ‘A−3’ as the refresh address RA_FREF based on the replaced switch signal of the low level.

The victim row generator may receive the aggressor row address ARA2 of ‘Y’ and the row gap signal CURR_RE of ‘RH’. The victim row generator may determine the ‘Y−1’ and ‘Y+1’ as the victim row address. The ‘Y−1’ and ‘Y+1’ generated by the victim row generator may be input to the victim row selector (e.g., 630 of FIG. 6) of the victim row determiner. The victim row selector may transmit the ‘Y−1’ to the second multiplexer based on the row selecting signal NEW_CAPTURE on the high level. When the ‘A−3’ is output as the refresh address RA_FREF and the replaced switch signal becomes the high level, the second multiplexer may output the ‘Y−1’ as the refresh address RA_FREF.

The victim row address of ‘Y−1’ may be output as the refresh address RA_FREF, and the memory device may transition the level of the row selecting signal NEW_CAPTURE to Low from High at a time tb5.

The memory device may transition the level of the target row refresh signal FREF_EN to Low from High at a time tb6. The memory device may transition the level of the difference signal DIST_M2 to Low from High in response to the transition of the target row refresh signal FREF_EN.

The memory device may store the row gap signal CURR_RE used at a second refresh of the time section (tb4 to tb6) as the row gap signal PREV_RE. For example, at the second refresh, the row gap signal CURR_RE may be ‘RH’, and the memory device may maintain the row gap signal PREV_RE at ‘RH’ at a time tb6. The memory device may determine the row gap signal CURR_RE to be used at the next refresh as ‘RH’. The memory device may complete the second refresh and may receive the activate command ACT.

The memory device may receive the activate command ACT and a row address B that corresponds to the same at a time tc1. The aggressor row selector of the memory device may generate the first condition signal COND1 on the high level based on the activate command ACT and the row address B at the time tc1. The aggressor row selector may determine the row address B as the aggressor row address ARA1 when the first condition signal COND1 and the refreshed signal FREF_DONE are the high level. The aggressor row selector may store the aggressor row address ARA1 in the first register.

The memory device may transition the refreshed signal FREF_DONE to the low level when the aggressor row address ARA1 of ‘B’ is stored in the first register. The memory device may transition the register signal REG_EMPTY to the low level when the aggressor row address ARA1 of ‘B’ is stored in the first register.

The memory device may calculate the difference value between the current aggressor row address ARA1 of ‘B’ and the previous aggressor row address ARA1 ‘A−2’. For example, the memory device may calculate the difference between ‘B’ and ‘A−2’. For example, the memory device may calculate the difference between rows corresponding to the row addresses ‘B’ and ‘A−2’. As the difference between ‘B’ and ‘A−2’ is not 2, the memory device may maintain the difference signals DIST_P2 and DIST_M2 at the low level.

The memory device may receive the activate command ACT and the row address that corresponds to the same at a time tc2. The aggressor row selector may generate a second condition signal COND2 of the high level based on the activate command ACT and the row address at the time tc2. The aggressor row selector may not generate the difference value signal SUB_AGGR when the second condition signal COND2 is on the high level and the row selecting signal NEW_CAPTURE is on the low level. As the difference value signal SUB_AGGR is not generated, the aggressor row selector may not change the aggressor row address ARA2, and the second register may maintain the stored ‘Y’.

The memory device may transition the level of the target row refresh signal FREF_EN to High from Low at the time tc3. The memory device may transition the refreshed signal FREF_DONE to the high level in response to the target row refresh signal FREF_EN on the high level.

The first register may output the aggressor row address ARA1 of ‘B’ in response to the target row refresh signal FREF_EN on the high level, and may transition the level of the register signal REG_EMPTY to High.

The memory device may operate the victim row determiner when the row gap signals CURR_RE and PREV_RE are ‘RH’. For example, the victim row determiner may not be operated when at least one of the row gap signals CURR_RE and PREV_RE is ‘ERH’.

The victim row generator of the victim row determiner may receive the aggressor row address ARA1 of ‘B’ and the row gap signal CURR_RE of ‘RH’. The victim row generator may determine the ‘B−1’ and ‘B+1’ as the victim row address. The ‘B−1’ and ‘B+1’ generated by the victim row generator may be input to the first multiplexer of the victim row determiner. The first multiplexer may transmit the ‘B-l’ to the second multiplexer based on the victim row switch signal on the low level. The second multiplexer may output the ‘B-l’ as the refresh address RA_FREF based on the replaced switch signal on the low level. The second multiplexer may transmit the ‘B+1’ to the second multiplexer when the victim row switch signal becomes the high level. The second multiplexer may output the ‘B+1’ as the refresh address RA_FREF based on the replaced switch signal on the low level. Hence, the ‘B−1’ and ‘B+1’ that is the victim row address may be sequentially refreshed.

The memory device may transition the level of the target row refresh signal FREF_EN to Low from High at the time tc4. The memory device may store the row gap signal CURR_RE used at a third refresh of the time section (tc3 to tc4) as the row gap signal PREV_RE. For example, at the third refresh, the row gap signal CURR_RE may be ‘RH’, and the memory device may maintain the row gap signal PREV_RE as ‘RH’ at the time tc4. The memory device may determine the row gap signal CURR_RE to be used at the next refresh as ‘RH’. The memory device may complete the third refresh and may receive the activate command ACT.

The memory device may receive the activate command ACT and a row address B+2 that corresponds to the same at a time td1. The aggressor row selector of the memory device may generate a first condition signal COND1 on the high level based on the activate command ACT and the row address B+2 at the time td1. The aggressor row selector may determine the row address B+2 as the aggressor row address ARA1 when the first condition signal COND1 and the refreshed signal FREF_DONE are on the high level. The aggressor row selector may store the aggressor row address ARA1 in the first register.

The memory device may transition the refreshed signal FREF_DONE to the low level when the aggressor row address ARA1 of ‘B+2’ is stored in the first register. The memory device may transition the register signal REG_EMPTY to the low level when the aggressor row address ARA1 of ‘B+2’ is stored in the first register.

The memory device may calculate the difference value between the current aggressor row address ARA1 of ‘B+2’ and the previous aggressor row address ARA1 of ‘B’. For example, the memory device may calculate the difference between ‘B+2’ and ‘B’. For example, the memory device may calculate the difference between rows corresponding to the row addresses ‘B+2’ and ‘B’. The current aggressor row address ARA1 is greater than the previous aggressor row address ARA1 by 2 so the memory device may generate a difference signal DIST_P2 on the high level. For example, the row corresponding to the current aggressor row address ARA1 of ‘B+2’ is greater than the row corresponding to the previous aggressor row address ARA1 of ‘B’ by 2 so the memory device may generate a difference signal DIST_P2 on the high level.

The memory device may receive the activate command ACT and the row address that corresponds to the same at the time td2. The aggressor row selector may generate a second condition signal COND2 on the high level based on the activate command ACT and the row address at the time td2. The second condition signal COND2 is on the high level and the row selecting signal NEW_CAPTURE is on the low level so the aggressor row selector may not generate the difference value signal SUB_AGGR. As the difference value signal SUB_AGGR is not generated, the aggressor row selector may not change the aggressor row address ARA2, and the second register may maintain the stored ‘Y’.

The memory device may transition the level of the target row refresh signal FREF_EN to High from Low at the time td3. The memory device may transition the refreshed signal FREF_DONE to the high level in response to the target row refresh signal FREF_EN on the high level. The first register may output the aggressor row address ARA1 of ‘B+2’ in response to the target row refresh signal FREF_EN of the high level, and may transition the level of the register signal REG_EMPTY to High.

The memory device may operate the victim row determiner when the row gap signals CURR_RE and PREV_RE are ‘RH’. That is, the victim row determiner may not be operated when at least one of the row gap signals CURR_RE and PREV_RE is ‘ERH’.

The victim row selector may transmit the ‘Y+1’ from among the ‘Y−1’ and ‘Y+1’ input at a fourth refresh of the time section (td3 to td5) to the second multiplexer based on the row selecting signal NEW_CAPTURE on the low level. The second multiplexer may output the ‘Y+1’ as the refresh address RA_FREF in response to the replaced switch signal of the high level. The victim row address ‘Y+1’ may be output as the refresh address RA_FREF, and the memory device may transition the level of the row selecting signal NEW_CAPTURE to High from Low at the time td4.

The victim row generator of the victim row determiner may receive the aggressor row address ARA1 of ‘B+2’ and the row gap signal CURR_RE of ‘RH’. The victim row generator may determine the ‘B+1’ and ‘B+3’ as the victim row address. The ‘B+1’ and ‘B+3’ generated by the victim row generator may be input to the first multiplexer of the victim row determiner. The first multiplexer may transmit the ‘B+3’ to the second multiplexer based on the victim row switch signal of the high level. The second multiplexer may output the ‘B+3’ as the refresh address RA_FREF based on the replaced switch signal on the low level.

The memory device may transition the level of the target row refresh signal FREF_EN to Low from High at a time td5. The memory device may transition the level of the difference signal DIST_P2 in response to the transition of the target row refresh signal FREF_EN.

The memory device may store the row gap signal CURR_RE used at the fourth refresh of the time section td3 to td5 as the row gap signal PREV_RE. For example, at the fourth refresh, the row gap signal CURR_RE may be ‘RH’, and the memory device may maintain the row gap signal PREV_RE as ‘RH’ at the time td5. The memory device may determine the row gap signal CURR_RE to be used at the next refresh as ‘RH’. The memory device may complete the fourth refresh and may receive the activate command ACT.

Hence, the memory device may increase defense performance by preventing the repeated victim row address from being refreshed.

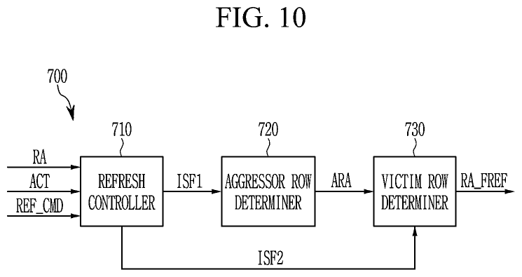

FIG. 10 shows a block diagram of a refresh control circuit 700 according to an embodiment.

Referring to FIG. 10, the refresh control circuit 700 according to an embodiment may generate a refresh address RA_FREF to be used for a target row refresh. The refresh control circuit 700 may include a refresh controller 710, an aggressor row determiner 720, and a victim row determiner 730.

The refresh controller 710 may receive the active signal ACT, the row address RA that corresponds to the active signal ACT, and the refresh command REF_CMD. The refresh controller 710 may generate internal signals ISF1 and ISF2 based on the active signal ACT, the row address RA, and the refresh command REF_CMD.

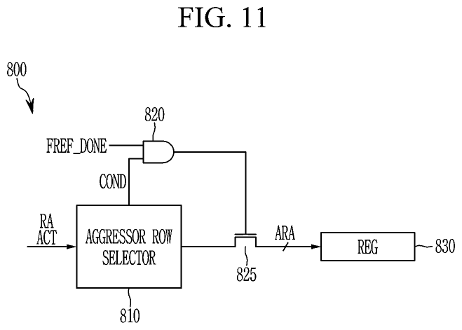

The internal signal ISF1 may include a refreshed signal, an active signal ACT, a row address RA, and a target row refresh signal. The internal signal ISF2 may include a victim row switch signal, a difference signal, and a row gap signal. The refresh controller 710 may transmit the internal signal ISF1 to the aggressor row determiner 720, and may transmit the internal signal ISF2 to the victim row determiner 730. The internal signal ISF1 and the internal signal ISF2 will be described later with reference to FIG. 11 to FIG. 13. According to an embodiment, the internal signal ISF1 and the internal signal ISF2 may also include at least one signal in common.

The aggressor row determiner 720 may determine the aggressor row address ARA based on the internal signal ISF1. In an embodiment, the aggressor row determiner 720 may generate a random number based on the internal signal ISF1, and may determine whether to determine the row address RA as the aggressor row address ARA based on the random number. In another embodiment, the aggressor row determiner 720 may count the activating number of the row address RA based on the active signal ACT and the row address RA. For example, the aggressor row determiner 720 may count the activating number of the row address RA in the target row refresh section. The aggressor row determiner 720 may determine the aggressor row address ARA based on the activating number. For example, the aggressor row determiner 720 may determine the row address RA having the greatest activating number as the aggressor row address ARA. The method for the aggressor row determiner 720 to determine the aggressor row address ARA is not specifically limited, and may be realized in various ways. The aggressor row determiner 720 may transmit the aggressor row address ARA to the victim row determiner 730.

The victim row determiner 730 may determine a plurality of victim row addresses based on the aggressor row address ARA. The victim row determiner 730 may determine one of the plurality of victim row address as the refresh address RA_FREF based on the internal signal ISF2. The memory device may perform a refresh based on the refresh address RA_FREF.

The victim row determiner 730 may determine the refresh address RA_FREF so that the refreshed victim row address may not be repeatedly refreshed. For example, the victim row determiner 730 may determine whether the difference between the previous aggressor row address ARA and the current aggressor row address ARA is 2. The victim row determiner 730 may skip the refresh of the refreshed victim row address based on the previous aggressor row address when the difference between the previous aggressor row address ARA and the current aggressor row address ARA is 2. Hence, power consumption of the memory device including the refresh control circuit 700 may be reduced.

A configuration for the aggressor row determiner 720 and the victim row determiner 730 to determine the addresses ARA and RA_FRER will be described later with reference to FIG. 11 to FIG. 13.

FIG. 11 shows a block diagram of an aggressor row determiner 800 according to an embodiment.

Referring to FIG. 11, the aggressor row determiner 800 according to an embodiment may determine the aggressor row address ARA based on the internal signal (e.g., ISF1 of FIG. 10). The internal signal may include a refreshed signal FREF_DONE, an active signal ACT, a row address RA, etc. In some embodiments, the active signal ACT and the row address RA may also be directly received from the memory controller (e.g., 120 of FIG. 1).

The aggressor row determiner 800 may include an aggressor row selector 810, an AND gate 820, a transistor 825, and a register (REG) 830). In some embodiments, the register 830 may also be arranged outside the aggressor row determiner 800.

The aggressor row selector 810 may receive the active signal ACT and the row address RA. The aggressor row selector 810 may determine the aggressor row address ARA based on the row address RA when receiving the active signal ACT.

The aggressor row selector 810 may generate a random number when receiving the active signal ACT. For example, the aggressor row selector 810 may include a random number generator. The content described with reference to FIG. 4 and FIG. 5 will be applied to the random number generator. No repeated description will be provided.

The aggressor row selector 810 may determine the aggressor row address ARA based on the generated random number. For example, the aggressor row selector 810 may generate a condition signal COND of the first level when the random number value is in the first range. The aggressor row selector 810 may generate a condition signal COND of the second level when the random number value is not in the first range.

The aggressor row selector 810 may transmit the row address RA as the aggressor row address ARA when the refreshed signal FREF_DONE is on the first level. The level of the refreshed signal FREF_DONE may be changed when the aggressor row address ARA is output. For example, the refreshed signal FREF_DONE may be changed to the second level from the first level. The refreshed signal FREF_DONE may be changed to the first level from the second level when the target row refresh is performed.

The AND gate 820 may receive the refreshed signal FREF_DONE and the condition signal COND. The AND gate 820 may perform an AND operation on the refreshed signal FREF_DONE and the condition signal COND, and may transmit an operation result to the transistor 825.

The AND gate 820 may output an operation result of the first level when the refreshed signal FREF_DONE and the condition signal COND are on the first level. The AND gate 820 may output an operation result of the second level when at least one of the refreshed signal FREF_DONE and the condition signal COND is on the second level.

The transistor 825 may be realized with the MOSFET. According to an embodiment, the transistor 825 may be realized a P-channel or N-channel transistor.

The transistor 825 may receive an operation result from the AND gate 820 through a gate and may be operated based on the operation result. For example, the transistor 825 may be turned on when receiving the operation result of the first level and may transmit the row address RA of the aggressor row selector 810 to the register 830 as the aggressor row address ARA. The row address RA may include a plurality of bits. The register 830 may receive the aggressor row address ARA and may store the same.

The transistor 825 may be turned off when receiving the operation result of the second level. For example, when receiving the row address RA, the transistor 825 may not transmit the row address RA to the register 830 based on the operation result of the second level.

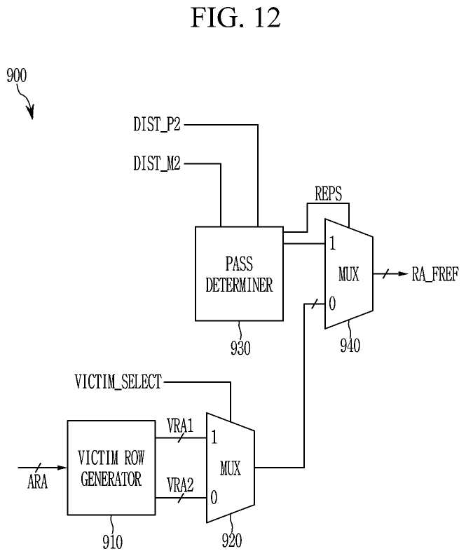

FIG. 12 shows a block diagram of a victim row determiner 900 according to an embodiment.

Referring to FIG. 12, the victim row determiner 900 according to an embodiment may generate victim row addresses VRA1 and VRA2 based on the aggressor row address ARA, and may generate a refresh address RA_FREF based on the victim row addresses VRA1 and VRA2.

The victim row determiner 900 may include a victim row generator 910, a first multiplexer 920, a pass determiner 930, and a second multiplexer 940.

The victim row generator 910 may generate victim row addresses VRA1 and VRA2 based on the aggressor row address ARA. For example, the victim row generator 910 may generate the victim row addresses VRA1 and VRA2 corresponding to the victim rows (or the victim word lines) which are disposed near an aggressor row (or an attack row) corresponding to the aggressor row address ARA and of which a physical position difference is 1. In some embodiments, the victim row generator 910 may receive a control signal from the refresh controller 710 of FIG. 10, and may also generate the victim row addresses VRA1 and VRA2 of which the physical position difference is 2 based on the control signal.

The first multiplexer 920 may receive the victim row addresses VRA1 and VRA2 from the victim row generator 910, and may receive the victim row switch signal VICTIM_SELECT from the refresh controller 710. The first multiplexer 920 may transmit one of the victim row addresses VRA1 and VRA2 to the second multiplexer 940 based on the victim row switch signal VICTIM_SELECT.

The refresh controller 710 may change the level of the victim row switch signal VICTIM_SELECT when a row corresponding to one of the victim row addresses VRA1 and VRA2 is refreshed. For example, the first multiplexer 920 may transmit the victim row address VRA2 to the second multiplexer 940 based on the victim row switch signal VICTIM_SELECT of the second level. The refresh controller 710 may output the victim row switch signal VICTIM_SELECT of the first level when a row corresponding to the victim row address VRA2 as the refresh address RA_FREF is refreshed. The first multiplexer 920 may transmit the victim row address VRA1 to the second multiplexer 940 based on the victim row switch signal VICTIM_SELECT of the first level. The refresh controller 710 may output the victim row switch signal VICTIM_SELECT of the second level when a row corresponding to the victim row address VRA1 as the refresh address RA_FREF is refreshed.

The pass determiner 930 may receive the difference signals DIST_P2 and DIST_M2 from the refresh controller 710. The pass determiner 930 may transmit a blank signal to the second multiplexer 940 based on the difference signals DIST_P2 and DIST_M2. In some embodiments, the blank signal may indicate a signal of the second level.

The refresh controller 710 may calculate the difference between the previous aggressor row address ARA and the current aggressor row address ARA. For example, the refresh controller 710 may include a subtractor. The subtractor may output the difference signal DIST_P2 of the first level when the current aggressor row address ARA is greater than the previous aggressor row address ARA by 2. The subtractor may output the difference signal DIST_M2 of the first level when the current aggressor row address ARA is less than the previous aggressor row address ARA by 2.

The refresh controller 710 may change the difference signal DIST_P2 or DIST_M2 to the second level from the first level when the target row refresh signal is changed to the first level from the second level.

The pass determiner 930 may generate the replaced switch signal REPS based on the difference signals DIST_P2 and DIST_M2. The pass determiner 930 may include an OR gate. The OR gate may perform an OR operation on the difference signals DIST_P2 and DIST_M2. For example, the OR gate may output the high level when at least one of the difference signals DIST_P2 and DIST_M2 is on the high level (e.g., the first level), and it may output the low level when the difference signals DIST_P2 and DIST_M2 are on the low level (e.g., the second level).

The pass determiner 930 may delay the replaced switch signal REPS and may output a resultant signal when the difference signal DIST_M2 is on the high level. For example, the pass determiner 930 may generate a replaced switch signal REPS so that the blank signal may be output as the refresh address RA_FREF when the victim row address VRA2 is output as the refresh address RA_FREF. When the difference signal DIST_P2 is on the high level, the pass determiner 930 may generate a replaced switch signal REPS so that the victim row address VRA1 may be output as the refresh address RA_FREF when the blank signal is output as the refresh address RA_FREF. The pass determiner 930 may transmit the replaced switch signal REPS to the second multiplexer 940.

The second multiplexer 940 may output the refresh address RA_FREF based on the replaced switch signal REPS. For example, the second multiplexer 940 may receive the replaced switch signal REPS of the second level and may output the address of the first multiplexer 920 as the refresh address RA_FREF. The second multiplexer 940 may receive the replaced switch signal REPS of the first level and may output the blank signal of the pass determiner 930 as the refresh address RA_FREF. The refresh may not be performed when the blank signal is output as the refresh address RA_FREF. That is, the memory device may skip the refresh based on the blank signal.

FIG. 13 shows a timing diagram illustrating a refresh operation of a memory device according to an embodiment.

Referring to FIG. 13, the memory device according to an embodiment may receive the command (e.g., the activate command ACT, the refresh command, etc.,) from the memory controller.

The memory device may generate internal signals based on the command of the memory controller. The internal signal may include a target row refresh signal FREF_EN, row gap signals CURR_RE and PREV_RE, a condition signal COND, a refreshed signal FREF_DONE, difference signals DIST_P2 and DIST_M2, a register signal REG_EMPTY, a victim row switch signal VICTIM_SELECT of FIG. 12, etc.

The memory device may determine the aggressor row address ARA based on the command and the internal signal of the memory controller. The memory device may determine the victim row address based on the aggressor row address ARA, and may output one of the victim row addresses as the refresh address RA_FREF. The memory device may perform a target row refresh operation by using the refresh address RA_FREF.

The memory device may generate row gap signals CURR_RE and PREV_RE. The row gap signals CURR_RE and PREV_RE may instruct to determine the row that is spaced from the row corresponding to the determined aggressor row address ARA by a predetermined gap as the victim row.

The row gap signal CURR_RE may indicate how far the row corresponding to the victim row address to be currently refreshed is spaced with respect to the row corresponding to the aggressor row address ARA. The row gap signal PREV_RE may indicate how far the row corresponding to the previously refreshed victim row address is spaced with respect to the row corresponding to previously determined aggressor row address. The victim row generator (e.g., 910 of FIG. 12) may determine the victim row address based on the row gap signal CURR_RE.

For example, when the row gap signal CURR_RE indicates ‘RH’, it may indicate the rows of ±1 with respect to the aggressor row address ARA. When the row gap signal CURR_RE indicates ‘ERH’, it may indicate the rows of ±2 with respect to the aggressor row address ARA. However, the embodiment is not limited thereto, and the memory device may indicate the rows of ±p (p is an integer that is greater than 2) with respect to the aggressor row address ARA.

The memory device may transition the level of the target row refresh signal FREF_EN to High from Low at the time ta11. For example, the memory device may generate a target row refresh signal FREF_EN in response to the refresh command of the memory controller.

The register (e.g., 830 of FIG. 11) of the memory device may store ‘A’ as the aggressor row address ARA at the time ta11. When the register stores the aggressor row address ARA, the register signal REG_EMPTY may be on the low level. The register may output the aggressor row address ARA of ‘A’ in response to the target row refresh signal FREF_EN on the high level, and may transition the level of the register signal REG_EMPTY to High at the time ta12.

The victim row generator (e.g., 910 of FIG. 12) of the victim row determiner (e.g., 900 of FIG. 12) may receive the aggressor row address ARA and the row gap signal CURR_RE. The victim row generator may confirm that the row gap signal CURR_RE is ‘RH’, and may determine ‘A−1’ and ‘A+1’ as the victim row address.

The victim row determiner may output ‘A−1’ and ‘A+1’ as the refresh address RA_FREF. The victim row determiner may sequentially output ‘A−1’ and ‘A+1’ based on the victim row switch signal. FIG. 13 shows that the victim row determiner outputs ‘A−1’ and outputs ‘A+1’, and the embodiment is not limited thereto, the victim row determiner may also be realized to output ‘A+1’ and output ‘A−1’.

The memory device may transition the level of the target row refresh signal FREF_EN to Low from High at the time ta13. The memory device may store the row gap signal CURR_RE used at a first refresh of the time section (ta11 to ta13) as the row gap signal PREV_RE. For example, the row gap signal CURR_RE may be ‘RH’ at the first refresh, and the memory device may change the row gap signal PREV_RE to ‘RH’ at the time ta13. The memory device may determine the row gap signal CURR_RE at the next refresh. For example, the memory device may maintain the row gap signal CURR_RE as ‘RH’ at the time ta13.

The memory device may complete the first refresh and may receive the activate command ACT.

The memory device may receive the activate command ACT and the row address A−2 that corresponds to the same at the time tb11. The aggressor row selector may generate the condition signal COND on the high level based on the activate command ACT and the row address A−2 at the time tb11. The aggressor row selector may maintain the condition signal COND at the high level for a unit time. That is, the aggressor row selector may transition the condition signal COND to the low level when a unit time passes. The aggressor row selector may determine the row address A−2 as the aggressor row address ARA when the condition signal COND and the refreshed signal FREF_DONE are on the high level. The aggressor row selector may store the aggressor row address ARA in the register.

The memory device may transition the refreshed signal FREF_DONE to the low level when the aggressor row address ARA of ‘A−2’ is stored in the register. The memory device may transition the register signal REG_EMPTY to the low level when the aggressor row address ARA of ‘A−2’ is stored in the register.

The memory device may calculate the difference value between the row corresponding to the current aggressor row address ARA and the previous aggressor row address ARA. For example, the memory device may calculate the difference between the row corresponding to the current aggressor row address ‘A−2’ and the row corresponding to the previous aggressor row address ‘A’. The row corresponding to the current aggressor row address ARA is less than the row corresponding to the previous aggressor row address ARA by 2, so the memory device may generate a difference signal DIST_M2 on the high level.

The memory device may transition the level of the target row refresh signal FREF_EN to High from Low at the time tb12. The memory device may transition the refreshed signal FREF_DONE to the high level in response to the target row refresh signal FREF_EN on the high level.

The register may output the aggressor row address ARA of ‘A−2’ in response to the target row refresh signal FREF_EN on the high level, and may transition the level of the register signal REG_EMPTY to High.

The memory device may operate the victim row determiner when the row gap signals CURR_RE and PREV_RE are ‘RH’. For example, the victim row determiner may not be operated when at least one of the row gap signals CURR_RE and PREV_RE is ‘ERH’.

The victim row generator of the victim row determiner may receive the aggressor row address ARA of ‘A−2’ and the row gap signal CURR_RE of ‘RH’. The victim row generator may determine the ‘A−3’ and ‘A-l’ as the victim row address. The ‘A−3’ and ‘A−1’ generated by the victim row generator may be input to the first multiplexer (e.g., 920 of FIG. 12) of the victim row determiner. The first multiplexer may transmit the ‘A−3’ to the second multiplexer (e.g., 940 of FIG. 12) based on the victim row switch signal on the low level. The second multiplexer may output the ‘A−3’ as the refresh address RA_FREF based on the replaced switch signal on the low level.

The pass determiner may generate a replaced switch signal based on the difference signals DIST_P2 and DIST_M2. For example, the pass determiner may generate a replaced switch signal of the first level when one of the difference signals DIST_P2 and DIST_M2 is on the first level. The pass determiner may delay the replaced switch signal and may output a resultant signal when the difference signal DIST_M2 is on the high level.

The pass determiner may transmit the blank signal to the second multiplexer. The second multiplexer may output the blank signal as the refresh address RA_FREF when the ‘A−3’ is output as the refresh address RA_FREF and the replaced switch signal becomes the high level. The memory device may skip the refresh in response to the blank signal. For example, the blank signal may have the second level.

The memory device may transition the level of the target row refresh signal FREF_EN to Low from High at the time tb13. The memory device may transition the level of the difference signal DIST_M2 to Low from High in response to the transition of the target row refresh signal FREF_EN.

The memory device may store the row gap signal CURR_RE used at a second refresh of the time section (tb12 to tb13) as the row gap signal PREV_RE. For example, the row gap signal CURR_RE may be ‘RH’ at the second refresh, and the memory device may maintain the row gap signal PREV_RE at ‘RH’ at the time tb13. The memory device may determine the row gap signal CURR_RE to be used at the next refresh as ‘RH’. The memory device may complete the second refresh and may receive the activate command ACT.

The memory device may receive the activate command ACT and the row address B that corresponds to the same at the time tc11. The aggressor row selector of the memory device may generate a condition signal COND on the high level based on the activate command ACT and the row address B at the time tc11. The aggressor row selector may determine the row address B as the aggressor row address ARA when the condition signal COND and the refreshed signal FREF_DONE are on the high level. The aggressor row selector may store the aggressor row address ARA in the register.

The memory device may transition the refreshed signal FREF_DONE to the low level when the aggressor row address ARA of ‘B’ is stored in the register. The memory device may transition the register signal REG_EMPTY to the low level when the aggressor row address ARA of ‘B’ is stored in the register.

The memory device may calculate the difference value between the current aggressor row address ARA of ‘B’ and the previous aggressor row address ARA of ‘A−2’. For example, the memory device may calculate the difference between ‘B’ and ‘A−2’. For example, the memory device may calculate the difference between rows corresponding to the current aggressor row address ‘B’ and the previous aggressor row address ‘A−2’. As the difference between ‘B’ and ‘A−2’ is not 2, the memory device may maintain the difference signals DIST_P2 and DIST_M2 at the low level.

The memory device may transition the level of the target row refresh signal FREF_EN to High from Low at the time tc12. The memory device may transition the refreshed signal FREF_DONE to the high level in response to the target row refresh signal FREF_EN on the high level.

The register may output the aggressor row address ARA of ‘B’ in response to the target row refresh signal FREF_EN on the high level, and may transition the level of the register signal REG_EMPTY to High.

The memory device may operate the victim row determiner when the row gap signals CURR_RE and PREV_RE are ‘RH’. That is, the victim row determiner may not be operated when at least one of the row gap signals CURR_RE and PREV_RE is ‘ERH’.

The victim row generator of the victim row determiner may receive the aggressor row address ARA of ‘B’ and the row gap signal CURR_RE of ‘RH’. The victim row generator may determine the ‘B−1’ and ‘B+1’ as the victim row address. The ‘B−1’ and ‘B+1’ generated by the victim row generator may be input to the first multiplexer of the victim row determiner. The first multiplexer may transmit the ‘B−1’ to the second multiplexer based on the victim row switch signal on the low level. The second multiplexer may output the ‘B−1’ as the refresh address RA_FREF based on the replaced switch signal on the low level. The second multiplexer may transmit the ‘B+1’ to the second multiplexer when the victim row switch signal becomes the high level. The second multiplexer may output the ‘B+1’ as the refresh address RA_FREF based on the replaced switch signal on the low level. Hence, ‘B−1’ and ‘B+1’ that is the victim row address may be sequentially refreshed.

The memory device may transition the level of the target row refresh signal FREF_EN to Low from High at the time tc13. The memory device may store the row gap signal CURR_RE used at a third refresh of the time section (tc12 to tc13) as the row gap signal PREV_RE. For example, the row gap signal CURR_RE may be ‘RH’ at the third refresh, and the memory device may maintain the row gap signal PREV_RE at ‘RH’ at the time tc13. The memory device may determine the row gap signal CURR_RE to be used at the next refresh as ‘RH’. The memory device may complete the third refresh and may receive the activate command ACT.

The memory device may receive the activate command ACT and the row address B+2 that corresponds to the same at the time td11. The aggressor row selector of the memory device may generate a condition signal COND on the high level based on the activate command ACT and the row address B+2 at the time td11. The aggressor row selector may determine the row address B+2 as the aggressor row address ARA when the condition signal COND and the refreshed signal FREF_DONE are on the high level. The aggressor row selector may store the aggressor row address ARA in the register.

The memory device may transition the refreshed signal FREF_DONE to the low level when the aggressor row address ARA of ‘B+2’ is stored in the register. The memory device may transition the register signal REG_EMPTY to the low level when the aggressor row address ARA of ‘B+2’ is stored in the register.

The memory device may calculate the difference value between the current aggressor row address ARA of ‘B+2’ and the previous aggressor row address ARA of ‘B’. For example, the memory device may calculate the difference between ‘B+2’ and ‘B’. For example, the memory device may calculate the difference between rows corresponding to the row addresses ‘B+2’ and ‘B’. The current aggressor row address ARA is greater than the previous aggressor row address ARA by 2 so the memory device may generate a difference signal DIST_P2 on the high level. For example, the row corresponding to the current aggressor row address ARA of ‘B+2’ is greater than the row corresponding to the previous aggressor row address ARA of ‘B’ by 2 so the memory device may generate a difference signal DIST_P2 on the high level.

The memory device may transition the level of the target row refresh signal FREF_EN to High from Low at the time td12. The memory device may transition the refreshed signal FREF_DONE to the high level in response to the target row refresh signal FREF_EN on the high level. The register may output the aggressor row address ARA of ‘B+2’ in response to the target row refresh signal FREF_EN on the high level, and may transition the level of the register signal REG_EMPTY to High.

The memory device may operate the victim row determiner when the row gap signals CURR_RE and PREV_RE are ‘RH’. For example, the victim row determiner may not be operated when at least one of the row gap signals CURR_RE and PREV_RE is ‘ERH’.

The pass determiner may transmit the blank signal to the second multiplexer, and the second multiplexer may output the blank signal to the refresh address RA_FREF in response to the replaced switch signal on the high level. The memory device may skip the refresh in response to the blank signal.

The victim row generator of the victim row determiner may receive the aggressor row address ARA of ‘B+2’ and the row gap signal CURR_RE of ‘RH’. The victim row generator may determine the ‘B+1’ and ‘B+3’ as the victim row address. The ‘B+1’ and ‘B+3’ generated by the victim row generator may be input to the first multiplexer of the victim row determiner. The first multiplexer may transmit the ‘B+3’ as the second multiplexer based on the victim row switch signal on the high level. The second multiplexer may output the ‘B+3’ as the refresh address RA_FREF based on the replaced switch signal on the low level.

The memory device may transition the level of the target row refresh signal FREF_EN to Low from High at the time td13. The memory device may transition the level of the difference signal DIST_P2 in response to the transition of the target row refresh signal FREF_EN.

The memory device may store the row gap signal CURR_RE used at the fourth refresh of the time section (td12 to td13) as the row gap signal PREV_RE. For example, the row gap signal CURR_RE may be ‘RH’ at the fourth refresh, and the memory device may maintain the row gap signal PREV_RE at ‘RH’ at the time td13. The memory device may determine the row gap signal CURR_RE to be used at the next refresh as ‘RH’. The memory device may complete the fourth refresh and may receive the activate command ACT.

Hence, the memory device may reduce power consumption by skipping the refresh of the victim row address.

FIG. 14 shows a flowchart of a refresh method according to an embodiment.

Referring to FIG. 14, the refresh method according to an embodiment may be performed by the memory device.

The memory device may receive the active signal and the row address that corresponds to the active signal (S1810). For example, the memory device may receive the active signal and the row address from the memory controller.

The memory device may determine the first aggressor row (S1820). The memory device may determine the first aggressor row based on the active signal. For example, the memory device may generate a random number when receiving the active signal. The memory device may or may not determine the row address as the first aggressor row based on the random number. The memory device may also determine the row address as the second aggressor row based on the random number. For example, the memory device may determine the row address as the first aggressor row when the random number is in the first range, and it may determine the row address as the second aggressor row when the random number is in the second range. In some embodiments, the first aggressor row address and the second aggressor row address may be stored in the different registers. However, the embodiment is not limited thereto, and the memory device may determine the aggressor row in many ways. For example, the memory device may count the activating number of the row address, and may also determine the aggressor row based on the activating number of the row address.

The memory device may determine whether the victim row is repeated (S1830). The memory device may determine at least one victim row based on the first aggressor row. The memory device may determine the row that is spaced by a predetermined interval with respect to the first aggressor row as the victim row based on the row gap signal.

The memory device may determine that the victim row is repeated when the first aggressor row address and the previous aggressor row address has the difference that is determined based on the current row gap signal and the previous row gap signal.

In an embodiment, the memory device may determine whether the difference between the first aggressor row address and the previous aggressor row address is 2 when the current row gap signal and the previous row gap signal are the first gap signal indicating the difference of 1.

In an embodiment, the memory device may determine whether the difference between the first aggressor row address and the previous aggressor row address is 3 when one of the current row gap signal and the previous row gap signal is the first gap signal and the other thereof is the second gap signal indicating the difference of 2.

In an embodiment, the memory device may determine whether the difference between the first aggressor row address and the previous aggressor row address is 4 when the current row gap signal and the previous row gap signal are the second gap signals.

Hence, the memory device may determine that the victim row is repeated when the first aggressor row address and the previous aggressor row address have a predetermined difference.

The memory device may determine the second aggressor row when the victim row is repeated (S1840). The memory device may read the second aggressor row stored by another register.

The memory device may replace the repeated victim row based on the second aggressor row (S1850). For example, the memory device may determine the row spaced by a predetermined interval with respect to the second aggressor row as the replaced victim row based on the current row gap signal. The memory device may output the replaced victim row address as the refresh address, and the replaced victim row may be refreshed.

However, the embodiment is not limited thereto, and the memory device may also skip the refresh of the repeated victim row.

The memory device may determine the victim row based on the first aggressor row when the victim row is not repeated (S1860). The memory device may determine the row spaced by a predetermined interval with respect to the first aggressor row as the victim row based on the current row gap signal. The memory device may output the victim row address as the refresh address, and the victim row may be refreshed.

FIG. 15 shows a block diagram of a computing system 1900 according to an embodiment.

Referring to FIG. 15, the computing system 1900 according to an embodiment may include a processor 1910, a memory 1920, a memory controller 1930, a storage device 1940, a communication interface 1950, and a bus 1960. The computing system 1900 may further include a general-purpose component.

The processor 1910 may control general operation of respective components of the computing system 1900. The processor 1910 may be realized with at least one of various processing units such as a central processing unit (CPU), an application processor (AP), or a graphic processing unit (GPU).

The memory 1920 may store various data and commands. The memory controller 1930 may control transmission of data or commands to/from the memory 1920. The memory 1920 and/or the memory controller 1930 may perform the refresh operation described with reference to FIG. 1 to FIG. 14. That is, the memory 1920 may perform the target row refresh in response to the command of the memory controller 1930. For example, the memory 1920 may determine the aggressor row address when receiving the activate command. The memory 1920 may determine the difference between the determined aggressor row address and the previous aggressor row address. The memory 1920 may change the victim row address or may skip the refresh of the victim row address based on the difference of the aggressor row addresses.

In an embodiment, the memory 1920 may replace one of the current victim row addresses with another address or may skip the refresh of the current victim row addresses when the difference between the aggressor row addresses is 2, and the victim row address indicates the rows of ±1 with respect to the aggressor row address at the previous refresh and the current refresh.

In an embodiment, the memory 1920 may replace one of the current victim row addresses with another address or may skip the refresh of one of the current victim row addresses when the difference between the aggressor row addresses is 3, the victim row address indicates the rows of ±1 with respect to the aggressor row address at one of the previous refresh and the current refresh, and the victim row address indicates the rows of ±2 with respect to the aggressor row address at the other thereof.

In an embodiment, the memory 1920 may replace one of the current victim row addresses with another address or may skip the refresh of one of the current victim row addresses when the difference between the aggressor row addresses is 4, and the victim row address indicates the rows of ±2 with respect to the aggressor row address at the previous refresh and the current refresh. However, the embodiment is not limited thereto, and the memory 1920 may replace the current victim row address with another address or may skip the refresh when the difference between the aggressor row addresses is equal to or greater than 5.

In some embodiments, the memory controller 1930 may be provided as a separate chip from the processor 1910. In some embodiments, the memory controller 1930 may be provided as an internal component of the processor 1910.

The storage device 1940 may non-temporarily store programs and data. In some embodiments, the storage device 1940 may be realized as a nonvolatile memory. The communication interface 1950 may support wired or wireless network communication of the computing system 1100. The communication interface 1950 may also support various communication methods other than the network communication. The bus 1960 may provide a communication function between the components of the computing system 1900. The bus 1960 may include at least one type of bus according to a communication protocol between the components.

FIG. 16 shows a memory module 2000 according to an embodiment.

Referring to FIG. 16, the memory module 2000 according to an embodiment may include a plurality of memory chips (DRAM) respectively including a memory cell array, a buffer chip (RCD) for routing a memory controller and transmitted/received signals or managing a memory operation of memory chips, and a power management chip (PMIC). The RCD may control the memory chips (DRAM) and the power management chip (PMIC) according to control by the memory controller. For example, the RCD may receive command signals, control signals, and clock signals (CLK) from the memory controller.

The memory chips (DRAM) may be connected to a corresponding one of data buffers (DB) through respectively corresponding data transmission lines and may transmit/receive data signals and data strobe signals. The memory chips (DRAM) may be connected to the data buffers (DB) through the respectively corresponding data transmission lines and may transmit/receive parity data and data strobe signals.

The memory module 2000 may include an electrically erasable programmable read-only memory (EEPROM). The EEPROM may include initial information or device information of the memory module 2000. For example, the EEPROM may include the information or the device information such as a module form, a module structure, storage capacity, a module type, or execution conditions of the memory module 2000. The memory controller may read the device information from the EEPROM and may recognize the memory module based on the device information when the memory system including the memory module 2000 boots.

The memory module 2000 may include a plurality of ranks. In an embodiment, the respective ranks may include eight bank groups. The respective bank groups may include four banks.

The memory module 2000 may perform the refresh operation described with reference to FIG. 1 to FIG. 14. That is, memory module 2000 may perform the target row refresh in response to the command of the memory controller. For example, the memory module 2000 may determine the aggressor row address when receiving the activate command. The memory module 2000 may determine the difference between the determined aggressor row address and the previous aggressor row address. The memory module 2000 may change the victim row address or may skip the refresh of the victim row address based on the difference between the aggressor row addresses.

In an embodiment, the memory module 2000 may replace one of the current victim row addresses with another address or may skip the refresh of one of the current victim row addresses when the difference between the aggressor row addresses is 2, and the victim row address indicates the rows of ±1 with respect to the aggressor row address at the previous refresh and the current refresh.

In an embodiment, the memory module 2000 may replace one of the current victim row addresses with another address or may skip the refresh of one of the current victim row addresses when the difference between the aggressor row addresses is 3, the victim row address indicates the rows of ±1 with respect to the aggressor row address at one of the previous refresh and the current refresh, and the victim row address indicates the rows of ±2 with respect to the aggressor row address at the other thereof.

In an embodiment, the memory module 2000 may replace one of the current victim row addresses with another address or may skip the refresh of one of the current victim row addresses when the difference between the aggressor row addresses is 4, and the victim row address indicates the rows of ±2 with respect to the aggressor row address at the previous refresh and the current refresh. However, the embodiment is not limited thereto, and the memory module 2000 may replace the current victim row address with another address or may skip the refresh when the difference between the aggressor row addresses is equal to or greater than 5.

FIG. 17 shows a semiconductor package 3000 according to an embodiment.

Referring to FIG. 17, the semiconductor package 3000 according to an embodiment may be a memory module including at least one stack semiconductor chip 3300 and a system on chip (SoC) 3400 mounted on the package substrate 3100 such as a printed circuit board (PCB). In some embodiments, an interposer 3200 may be optionally further provided on the package substrate 3100. The stack semiconductor chip 3300 may be formed of a chip on chip (CoC).

The stack semiconductor chip 3300 may include at least one memory chip 3320 stacked on the buffer chip 3310 such as a logic chip. The buffer chip 3310 and the at least one memory chip 3320 may be connected to by a through silicon via (TSV). The buffer chip 3310 may perform a training operation on the memory chip 3320. For example, the stack semiconductor chip 3300 may be a high bandwidth memory (HBM) of 500 GB/sec to 1 TB/sec or more.

The at least one memory chip 3320 may perform the refresh operation described with reference to FIG. 1 to FIG. 14. That is, the at least one memory chip 3320 may perform the target row refresh in response to the command of the memory controller. For example, the at least one memory chip 3320 may determine the aggressor row address when receiving the activate command. The at least one memory chip 3320 may determine the difference between the determined aggressor row address and the previous aggressor row address. The at least one memory chip 3320 may change the victim row address or may skip the refresh of the victim row address based on the difference between the aggressor row addresses.

In an embodiment, the at least one memory chip 3320 may replace one of the current victim row addresses with another address or may skip the refresh of one of the current victim row addresses when the difference between the aggressor row addresses is 2, and the victim row address indicates the rows of ±1 with respect to the aggressor row address at the previous refresh and the current refresh.

In an embodiment, the at least one memory chip 3320 may replace one of the current victim row addresses with another address or may skip the refresh of one of the current victim row addresses when the difference between the aggressor row addresses is 3, the victim row address indicates the rows of ±1 with respect to the aggressor row address at one of the previous refresh and the current refresh, and the victim row address indicates the rows of ±2 with respect to the aggressor row address at the other thereof.

In an embodiment, at least one memory chip 3320 may replace one of the current victim row addresses with another address or may skip refreshing one of the current victim row addresses when the difference between the aggressor row addresses is 4, and the victim row address at the previous refresh and the current refresh indicates the rows of ±2 with respect to the aggressor row address. However, the embodiment is not limited thereto, and at least one memory chip 3320 may replace the current victim row address with another address or may skip refreshing when the difference between the aggressor row addresses is equal to or greater than 5.

In some embodiments, each component or a combination of two or more components described with reference to FIG. 1 to FIG. 17 may be implemented with a digital circuit, a programmable or non-programmable logic device or array, an application specific integrated circuit (ASIC), or the like.

While this disclosure has been described in connection with what is presently considered to be practical embodiments, it is to be understood that the present invention is not limited to the disclosed embodiments. On the contrary, it is intended to cover various modifications and equivalent arrangements included within the spirit and scope of the present invention as set forth in the appended claims.

What is claimed is:

1. A memory device comprising:
a refresh controller configured to generate a first control signal and a second control signal based on an activate command and a row address that corresponds to the activate command;
an aggressor row determiner configured to determine the row address as an aggressor row address based on the first control signal; and
a victim row determiner configured to determine a victim row address based on the aggressor row address, and determine whether to output the victim row address as a refresh address based on the second control signal,
wherein the memory device is configured to perform a refresh on a row corresponding to the refresh address.

2. The memory device of claim 1, wherein:
the refresh controller is configured to determine a difference value between a row corresponding to the aggressor row address and a row corresponding to a previous aggressor row address and generate the second control signal including the difference value, and
the victim row determiner is configured to determine whether to output the victim row address based on the difference value.

3. The memory device of claim 1, wherein the victim row determiner is configured to replace the victim row address with another address or not to output the victim row address based on the second control signal.

4. The memory device of claim 3, wherein:
the victim row determiner includes:
a victim row generator configured to generate a first victim row address and a second victim row address based on a first aggressor row address and generate a third victim row address and a fourth victim row address based on a second aggressor row address;
a victim row selector configured to generate a replaced switch signal and output one of the third victim row address and the fourth victim row address based on a difference signal and a row selecting signal from among the second control signal;
a first multiplexer configured to output one of the first victim row address and the second victim row address based on a victim row switch signal from among the second control signal; and
a second multiplexer configured to output one of the first to fourth victim row addresses from the victim row selector and the first multiplexer as the refresh address based on the replaced switch signal.

5. The memory device of claim 4, wherein, the memory device is configured such that the victim row selector:
outputs the third victim row address when the row selecting signal is on a second level, and
outputs the fourth victim row address when the row selecting signal is on a first level higher than the second level.

6. The memory device of claim 4, wherein, the memory device is configured such that the victim row selector generates the replaced switch signal when the difference signal is on a first level.

7. The memory device of claim 6, wherein, the memory device is configured such that the victim row selector delays the replaced switch signal when the difference signal indicates that a row corresponding to the aggressor row address is less than a row corresponding to a previous aggressor row address by a predetermined difference.

8. The memory device of claim 4, wherein, the memory device is configured such that the refresh controller transitions a level of the victim row switch signal when one of the first victim row address and the second victim row address is output as the refresh address.

9. The memory device of claim 4, wherein the victim row generator is configured to generate the victim row address from the aggressor row address based on a row gap signal indicating a difference between an aggressor row corresponding to the aggressor row address and a victim row corresponding to the victim row address.

10. The memory device of claim 9, wherein, when a difference between the aggressor row and a row corresponding to a previous aggressor row address is the same as a difference determined based on a current row gap signal and a previous row gap signal, the memory device is configured such that the victim row determiner replaces the victim row address with another address or does not output the victim row address.

11. The memory device of claim 10, wherein, the memory device is configured such that the victim row determiner determines:
whether the difference between the aggressor row and the row corresponding to the previous aggressor row address is 2 when the current row gap signal and the previous row gap signal are a first gap signal indicating the difference of 1,
whether the difference between the aggressor row and the row corresponding to the previous aggressor row address is 3 when one of the current row gap signal and the previous row gap signal is the first gap signal, and the other thereof is a second gap signal indicating the difference of 2, and
whether the difference between the aggressor row and the row corresponding to the previous aggressor row address is 4 when the current row gap signal and the previous row gap signal are the second gap signal.

12. The memory device of claim 1, wherein the aggressor row determiner includes:
an aggressor row selector configured to determine the row address as a first aggressor row address or a second aggressor row address based on the activate command;
a first register configured to store the first aggressor row address and output the first aggressor row address in response to a target row refresh signal of a first level; and
a second register configured to store the second aggressor row address and output the second aggressor row address in response to the target row refresh signal of the first level.

13. The memory device of claim 12, wherein the aggressor row selector is configured to:
generate a random number based on the activate command, and
generate condition signals for classifying the row address based on the random number.

14. The memory device of claim 13, wherein the aggressor row selector is configured to:
generate a first condition signal for classifying the row address as the first aggressor row address when the random number is in a first range, and
generate a second condition signal for classifying the row address as the second aggressor row address when the random number is in a second range.

15. The memory device of claim 14, wherein the aggressor row determiner further includes:
a first AND gate configured to perform an AND operation on the first condition signal and a refreshed signal and output a first operation signal;
a first transistor configured to be turned on when the first operation signal is on the first level, and transmit the first aggressor row address to the first register;
a second AND gate configured to perform an AND operation on the second condition signal and a row selecting signal and output a second operation signal; and
a second transistor configured to be turned on when the second operation signal is on the first level, and transmit the second aggressor row address to the second register.

16. The memory device of claim 1, wherein the aggressor row determiner includes:
an aggressor row selector configured to generate a condition signal for determining the row address as the aggressor row address based on the activate command;
an AND gate configured to perform an AND operation on the condition signal and a refreshed signal and output an operation signal;
a transistor configured to receive the operation signal through a gate, be turned on when the operation signal is on a first level, and transmit the aggressor row address; and
a register configured to store the aggressor row address and output the aggressor row address in response to a target row refresh signal on the first level.

17. The memory device of claim 16, wherein the victim row determiner includes:
a victim row generator configured to generate a first victim row address and a second victim row address based on the aggressor row address;
a first multiplexer configured to output one of the first victim row address and the second victim row address based on a victim row switch signal from among the second control signal;
a pass determiner configured to generate a replaced switch signal and a blank signal based on a difference signal from among the second control signal; and
a second multiplexer configured to output an output from the first multiplexer or the pass determiner as the refresh address based on the replaced switch signal.

18. A memory device comprising:
a memory cell array including a plurality of memory cells; and
a refresh control circuit configured to:
determine an aggressor row address based on an active signal and a row address that corresponds to the active signal,
determine a victim row address based on the aggressor row address, and
determine a difference between a row corresponding to the aggressor row address and a row corresponding to a previous aggressor row address,
wherein, when an absolute value of the difference is a reference value, the memory device is configured such that the refresh control circuit skips a refresh on the row corresponding to the victim row address that is previously refreshed or refreshes on another row.

19. The memory device of claim 18, wherein the reference value is determined based on a gap signal for indicating a difference between the row corresponding to the aggressor row address and the row corresponding to the victim row address adjacent to the row corresponding to the aggressor row address.

20. A refresh method of a memory device, the method comprising:
receiving an active signal and a row address that corresponds to the active signal;
determining a first aggressor row based on the active signal and the row address;
determining whether a first victim row adjacent to the first aggressor row repeats a previously refreshed row;
determining a second aggressor row that is different from the first aggressor row when the first victim row repeats the same, and determining a second victim row adjacent to the second aggressor row to be refreshed; and
determining the first victim row to be refreshed when the first victim row does not repeat the same.
